(19) United States
(12) Patent Application Publication
(10) Pub. No.: US 2024/0387327 A1
(43) Pub. Date: Nov. 21, 2024

(54) SEMICONDUCTOR DEVICE AND MANUFACTURING METHOD THEREOF

(71) Applicant: Taiwan Semiconductor Manufacturing Company, Ltd., Hsinchu (TW)

(72) Inventor: Chih-Yang CHEN, Hsinchu (TW)

(73) Assignee: Taiwan Semiconductor Manufacturing Company, Ltd., Hsinchu (TW)

(21) Appl. No.: 18/198,318

(22) Filed: May 17, 2023

(51) Int. Cl. H01L 23/48; H01L 21/8238; H01L 27/092; H01L 29/06; H01L 29/423; H01L 29/66; H01L 29/775; H01L 29/786

(52) U.S. Cl. CPC H01L 23/481; H01L 21/823807; H01L 21/823871; H01L 27/092; H01L 29/0673; H01L 29/42392; H01L 29/66439; H01L 29/66545; H01L 29/775; H01L 29/78696

(57) ABSTRACT

A semiconductor device includes a substrate, a first active structure, a first metal gate, a trench, an epitaxy and a back-side conductive via. The first active structure and a second active structure are formed on the substrate and arranged in a first direction. The first metal gate is formed on the first active structures. The trench passes through adjacent two of the first active structure and the second active structure in a second direction. The epitaxy formed on within the trench. The back-side conductive via is formed within the substrate and connecting the epitaxy. The first insulation layer is formed under the first metal gate and extending to a first lateral surface of the back-side conductive via.

### BACKGROUND

A semiconductor device includes a conductive via and at least one epitaxy formed two metal gates. The conductive via may be electrically connected to the epitaxy. However, in process of forming the conductive via, the conductive via may extend to the metal gate to cause the electrical shorting.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1a illustrates a schematic diagram of a cross-sectional view of a semiconductor device in a first direction;

FIG. 1b illustrates a schematic diagram of a cross-sectional view of a semiconductor device in a second direction;

FIG. 2a illustrates a schematic diagram of a cross-sectional view of a semiconductor device in the first direction;

FIG. 2b illustrates a schematic diagram of a cross-sectional view of a semiconductor device in the second direction;

FIG. 3a illustrates a schematic diagram of a cross-sectional view of a semiconductor device in the first direction;

FIG. 3b illustrates a schematic diagram of a cross-sectional view of a semiconductor device in the second direction;

FIG. 4a illustrates a schematic diagram of a cross-sectional view of a semiconductor device in the first direction;

FIG. 4b illustrates a schematic diagram of a cross-sectional view of a semiconductor device in the second direction;

FIGS. 5A_a to 5X_b illustrate schematic diagrams of manufacturing processes of the semiconductor device 100 of FIGS. 1a and 1b;

FIGS. 6A_a to 6B_b illustrate schematic diagrams of manufacturing processes of the semiconductor device of FIGS. 2a and 2b;

FIGS. 7A_a to 7T_b illustrate schematic diagrams of manufacturing processes of the semiconductor device of FIGS. 3a and 3b; and

FIGS. 8A_a to 8G_b illustrate schematic diagrams of manufacturing processes of the semiconductor device 400 of FIGS. 4a and 4b.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for case of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

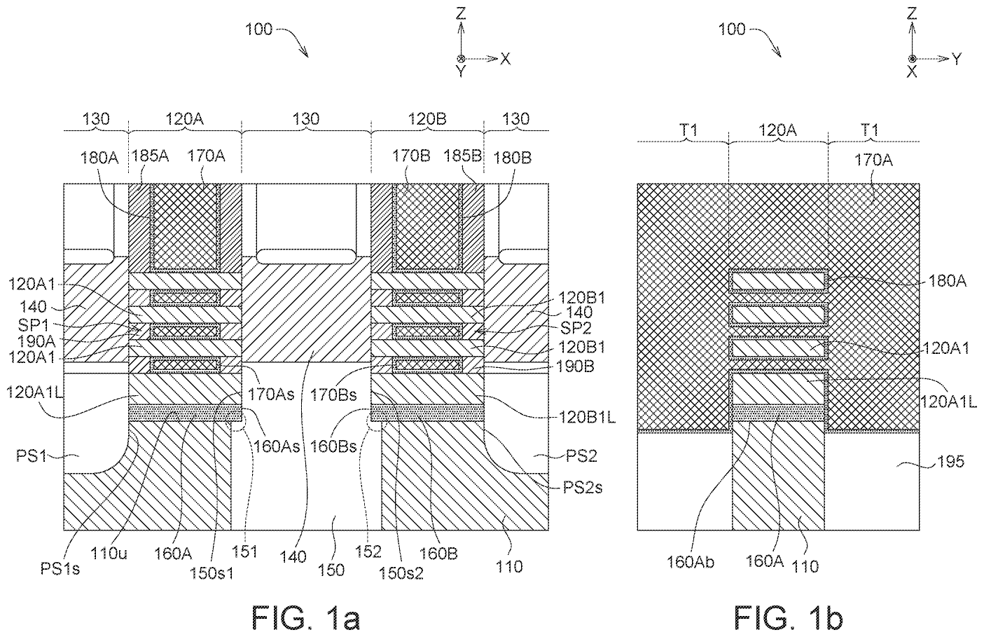

Referring to FIGS. 1a and 1b, FIG. 1a illustrates a schematic diagram of a cross-sectional view of a semiconductor device 100 in a first direction, and FIG. 1b illustrates a schematic diagram of a cross-sectional view of a semiconductor device 100 in a second direction. The semiconductor device 100 may be, for example, a nano-sheet structure, fork-sheet structure or a combination thereof.

As illustrated in FIGS. 1a and 1b, the semiconductor device 100 includes a substrate 110, a plurality of active structures (at least include a first active structure 120A and a second active structure 120B), at least one trench 130, at least one epitaxy 140, at least one back-side conductive via 150, at least one insulation layer (at least includes a first insulation layer 160A and a second insulation layer 160B), at least one metal gate (at least include a first metal gate 170A and a second metal gate 170B), at least one high-k dielectric layer (at least include a first high-k dielectric layer 180A and a second high-k dielectric layer 180B), at least one spacer layer (at least include a first spacer layer 185A and a second spacer layer 185B), at least one inner spacer (at least include a first inner spacer 190A and a second inner spacer 190B) and an oxide layer 195.

As illustrated in FIGS. 1a and 1b, the first active structure 120A and the second active structure 120B are formed on the substrate 110 and arranged in the first direction (for example, X axis). The first metal gate 170A is formed on the first active structure 120A. The trench 130 passes through adjacent two of the first active structure 120A and the second active structure 120B in a second direction (for example, Y axis). The epitaxy 140 is formed within the trench 130. The back-side conductive via 150 is formed within the substrate and is connected to the epitaxy 140. The first insulation layer 160A is formed under the first metal gate 170A and extends to a first lateral surface 150s1 of the back-side conductive via 150. As a result, the first insulation layer 160A could block the back-side conductive via 150 from being in contact with the first metal gate 170A, and accordingly it could avoid the electrical shorting.

As illustrated in FIGS. 1a and 1b, the first insulation layer 160A has a lateral surface 160As, and the first metal gate 170A has a lateral surface 170As, wherein the lateral surface 160As is closer to the first lateral surface 150s1 than the lateral surface 170As of the first metal gate 170A, and thus the first insulation layer 160A could block the back-side conductive via 150 from being in contact with the first metal gate 170A, and accordingly it could avoid the electrical shorting.

The substrate 110 is, for example, a silicon wafer.

As illustrated in FIGS. 1a and 1b, the first active structure 120A includes a plurality of the sheets 120A1, wherein the adjacent two sheets 120A1 are spaced from each other by a first space SP1, the first metal gate 170A is formed within the first active structure 120A, wherein a portion of the first metal gate 170A fills a portion of the space SP1 and retains another portion of the space SP1 to form a recess, and the first inner spacer 190A is formed within the recess. The first spacer layer 185A and the first inner space layer 190A are formed within the first active structure 120A. The first high-k dielectric layer 180A covers the sheets 120A1, formed between the first metal gate 170A and the sheets 120A1, and formed between the first metal gate 170A and the first spacer layer 185A.

Similarly, the second active structure 120B includes a plurality of the sheets 120B1, wherein the adjacent two sheets 120B1 are spaced from each other by a second space SP2, the second metal gate 170B is formed within the second active structure 120B, wherein a portion of the second metal gate 170B fills a portion of the space SP2 and retains another portion of the space SP2 to form a recess, and the second inner spacer 190B is formed within the recess. The second spacer layer 185B and the second inner space layer 190B are formed within the second active structure 120B. The second high-k dielectric layer 180B covers the sheets 120B1, formed between the second metal gate 170B and the sheets 120B1, and formed between the second metal gate 170B and the second spacer layer 185B.

As illustrated in FIGS. 1a and 1b, the second insulation layer 160B is formed under the first metal gate 170A and extends to a second lateral surface 150s2 of the back-side conductive via 150. As a result, the second insulation layer 160B could block the back-side conductive via 150 from being in contact with the second metal gate 170B, and accordingly it could avoid the electrical shorting.

As illustrated in FIGS. 1a and 1b, the second insulation layer 160B has a lateral surface 160Bs, and the second metal gate 170B has a lateral surface 170Bs, wherein the lateral surface 160Bs is closer to the second lateral surface 150s2 than the lateral surface 170Bs of the second metal gate 170B, and thus the second insulation layer 160B could block the back-side conductive via 150 from being in contact with the second metal gate 170B, and accordingly it could avoid the electrical shorting.

In a SPR (Super Power Rail) SAC (Self-Aligned Contact) process, an end of the first insulation layer 160A is not removed, and accordingly it may form a step structure 151 of the back-side conductive via 150. Similarly, in a SPR SAC process, an end of the second insulation layer 160B, and accordingly it may form a step structure 152 of the back-side conductive via 150.

As illustrated in FIGS. 1a and 1b, the semiconductor device 100 further includes a first pure silicon layer (non-doped) PS1 adjacent to the first active structure 120A, the first pure silicon layer PS1 is formed on a bottom of another trench 130 adjacent to the first active structure 120A. The first insulation layer 160A extends between the first pure silicon layer PS1 and the back-side conductive via 150 in the first direction. For example, the first pure silicon layer PS1 extends to a lateral surface PS1s of the first pure silicon layer PS1. Similarly, the semiconductor device 100 further includes a second pure silicon layer (non-doped) PS2 adjacent to the second active structure 120B, the second pure silicon layer PS2 is formed on a bottom of another trench 130 adjacent to the second active structure 120B. The second insulation layer 160B extends between the second pure silicon layer PS2 and the back-side conductive via 150 in the first direction. For example, the second pure silicon layer PS2 extends to a lateral surface PS2s of the second pure silicon layer PS2.

As illustrated in FIGS. 1a and 1b, the substrate 110 has an upper surface 110u on which the first active structure 120A and the second active structure 120B are formed, and the first insulation layer 160A and the second insulation layer 160B are formed on the upper surface 110u. One of the sheets 120A1 (for example, the lowermost sheet 120A1L) and the substrate 110 may be separated from each other by the first insulation layer 160A. Similarly, one of the sheets 120B1 (for example, the lowermost sheet 120B1L) and the substrate 110 may be separated from each other by the second insulation layer 160B.

As illustrated in FIGS. 1a and 1b, the first high-k dielectric layer 180A and the first insulation layer 160A may be formed of the same material including, for example, high-k dielectric material. In an embodiment, the first high-k dielectric layer 180A and the first insulation layer 160A may be formed in different processes.

The High-k dielectric layer may include single-layer or multi-layers of dielectric material, such as hafnium oxide (HfO₂), hafnium silicate (HfSiO), HfSiON, HfTaO, HfTiO, hafnium zirconium oxide (HfZrO), zirconium oxide (ZrO₂), silicon nitride, silicon oxynitride, silicon carbide, silicon carbonitride, silicon oxycarbonitride, silicon oxycarbide, or other suitable dielectric material and/or a combination thereof. As used herein, the term “high-k” refers to a high dielectric constant. In the field of semiconductor device structures and manufacturing processes, high-k refers to a dielectric constant that is greater than the dielectric constant of SiO₂ (e.g., greater than 3.9).

As illustrated in FIGS. 1a and 1b, the first active structure 120A extending in the first direction defines OD region, for example. The adjacent two OD regions are spaced from each other by an interval T1. The oxide layer 195 is, for example, a STI (Shallow Trench Isolation). The oxide layer 195 is formed within a bottom portion of the interval T1. In the present embodiment, the oxide layer 195 is lower than the first insulation layer 160A and the second insulation layer 160B. For example, the oxide layer 195 is lower than a lower surface 160Ab of the first insulation layer 160A and a lower surface (not illustrated) of the second insulation layer 160B.

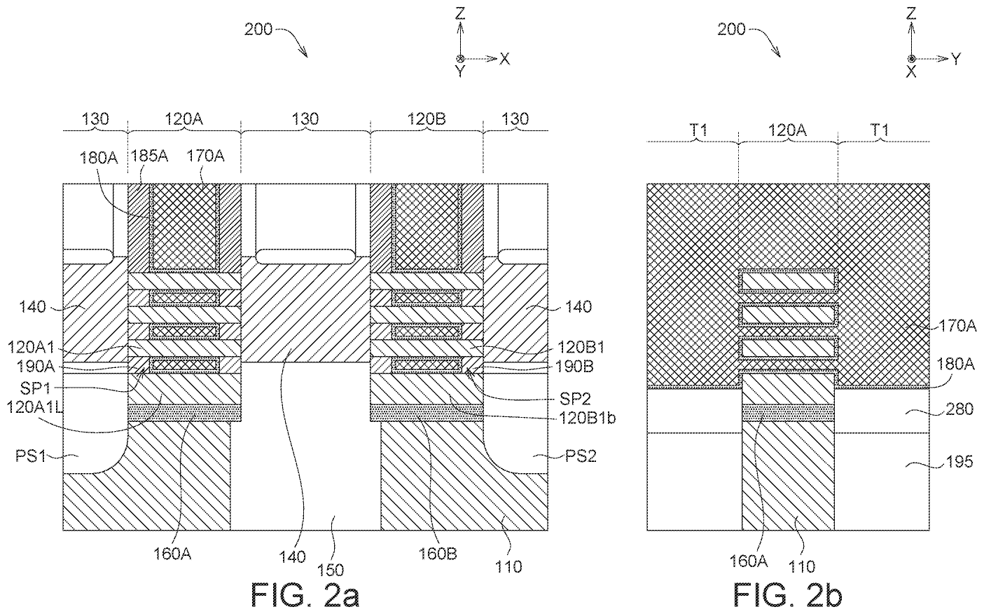

Referring to FIGS. 2a and 2b, FIG. 2a illustrates a schematic diagram of a cross-sectional view of a semiconductor device 200 in the first direction, and FIG. 2b illustrates a schematic diagram of a cross-sectional view of a semiconductor device 200 in the second direction. The semiconductor device 200 may be, for example, a nano-sheet structure, fork-sheet structure or a combination thereof.

As illustrated in FIGS. 2a and 2b, the semiconductor device 200 includes the substrate 110, a plurality of active structures (at least include a first active structure 120A and a second active structure 120B), at least one trench 130, at least one epitaxy 140, at least one back-side conductive via 150, at least one insulation layer (at least includes the first insulation layer 160A and the second insulation layer 160B), at least one metal gate (at least include the first metal gate 170A and the second metal gate 170B), at least one high-k dielectric layer (at least include the first high-k dielectric layer 180A and the second high-k dielectric layer 180B), at least one spacer layer (at least include the first spacer layer 185A and the second spacer layer 185B), at least one inner spacer (at least include the first inner spacer 190A and the second inner spacer 190B), the oxide layer 195 and at least one cushion layer 280.

The semiconductor device 200 includes the features (structure, connection relationship, material, etc.) similar to or the same as that of the semiconductor device 100, and the difference is that, for example, the semiconductor device 200 further includes at least one cushion layer 280. The cushion layers 280 are formed within the intervals T1 and over the oxide layer 195, located at two opposite sides of the first active structure 120A and located at two opposite sides of the second active structure 120B (not illustrated in FIG. 2b). The cushion layer 280 may be formed of a material including, for example, a low-K material, such as SiCO, SiON, SiCON, etc. The cushion layer 280 is lower than the first metal gate 170A and the second metal gate 170B, and higher than the first insulation layer 160A and the second insulation layer 160B.

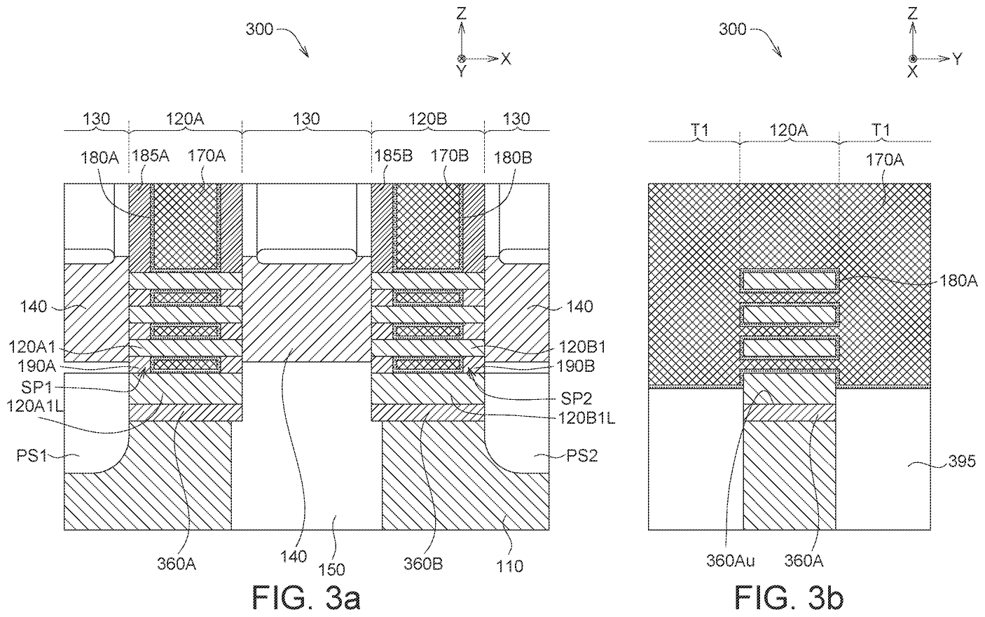

Referring to FIGS. 3a and 3b, FIG. 3a illustrates a schematic diagram of a cross-sectional view of a semiconductor device 300 in the first direction, and FIG. 3b illustrates a schematic diagram of a cross-sectional view of a semiconductor device 300 in the second direction. The semiconductor device 300 may be, for example, a nano-sheet structure, fork-sheet structure or a combination thereof.

As illustrated in FIGS. 3a and 3b, the semiconductor device 300 includes the substrate 110, a plurality of active structures (at least include a first active structure 120A and a second active structure 120B), at least one trench 130, at least one epitaxy 140, at least one back-side conductive via 150, at least one insulation layer (at least includes a first insulation layer 360A and a second insulation layer 360B), at least one metal gate (at least include the first metal gate 170A and the second metal gate 170B), at least one high-k dielectric layer (at least include the first high-k dielectric layer 180A and the second high-k dielectric layer 180B), at least one spacer layer (at least include the first spacer layer 185A and the second spacer layer 185B), at least one inner spacer (at least include the first inner spacer 190A and the second inner spacer 190B) and an oxide layer 395.

The semiconductor device 300 includes the features (structure, connection relationship, material, etc.) similar to or the same as that of the semiconductor device 100, and the difference is that, for example, the oxide layer 395 is higher than the first insulation layer 360A and the second insulation layer 360B (the second insulation layer 360B is shown in FIG. 3a). For example, the oxide layer 395 is higher than an upper surface 360Au of the first insulation layer 360A and upper surface (not illustrated) of the second insulation layer 360B.

As illustrated in FIGS. 3a and 3b, the first inner spacer 190A is formed on the first active structure 120A, wherein the first inner spacer 190A is formed within the first space SP1, and the second inner spacer 190B is formed on the second active structure 120B, wherein the second inner spacer 190B is formed within the second space SP2. In the present embodiment, the first inner spacer 190A and the first insulation layer 360A may be formed of the same material including, for example, silicon oxide, silicon nitride, silicon carbide, silicon oxynitride, silicon oxycarbide, other suitable materials or a combination thereof. The first inner spacer 190A and the first insulation layer 360A may be formed in the same process, for example, deposition.

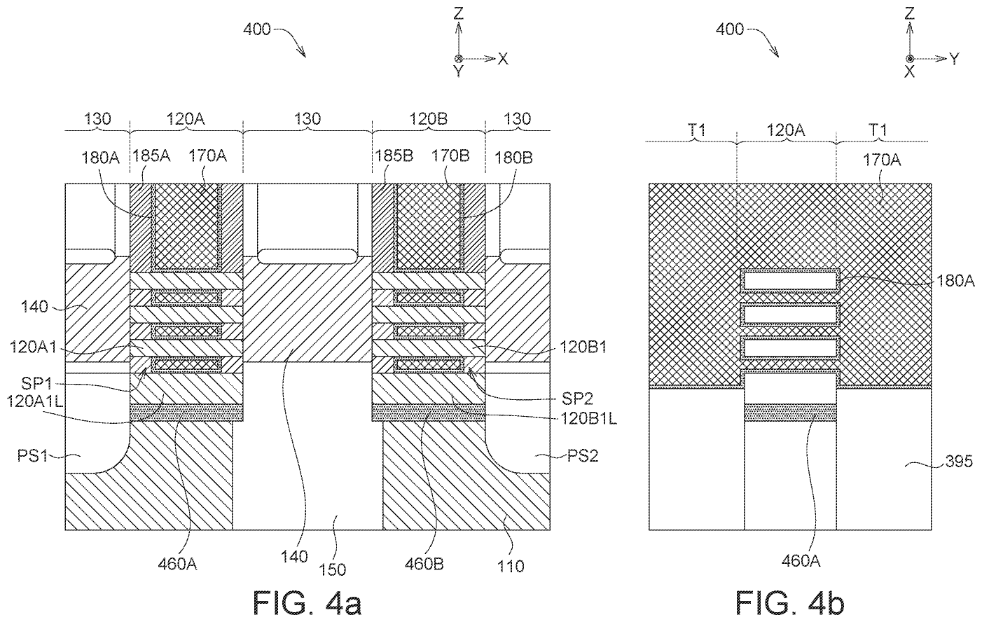

Referring to FIGS. 4a and 4b, FIG. 4a illustrates a schematic diagram of a cross-sectional view of a semiconductor device 400 in the first direction, and FIG. 4b illustrates a schematic diagram of a cross-sectional view of a semiconductor device 400 in the second direction. The semiconductor device 400 may be, for example, a nano-sheet structure, fork-sheet structure or a combination thereof.

As illustrated in FIGS. 4a and 4b, the semiconductor device 400 includes the substrate 110, a plurality of active structures (at least include a first active structure 120A and a second active structure 120B), at least one trench 130, at least one epitaxy 140, at least one back-side conductive via 150, at least one insulation layer (at least includes a first insulation layer 460A and a second insulation layer 460B), at least one metal gate (at least include the first metal gate 170A and the second metal gate 170B), at least one high-k dielectric layer (at least include the first high-k dielectric layer 180A and the second high-k dielectric layer 180B), at least one spacer layer (at least include the first spacer layer 185A and the second spacer layer 185B), at least one inner spacer (at least include the first inner spacer 190A and the second inner spacer 190B), the oxide layer 395.

The semiconductor device 400 includes the features (structure, connection relationship, material, etc.) similar to or the same as that of the semiconductor device 300, and the difference is that, for example, the first insulation layer 460A and the second insulation layer 460B are formed of a material different from that of the first insulation layer 360A and the second insulation layer 360B.

As illustrated in FIGS. 4a and 4b, in the present embodiment, the first high-k dielectric layer 180A and the first insulation layer 460A are formed of the same material including, for example, high-k dielectric material. Similarly, the second high-k dielectric layer 180B and the second insulation layer 460B are formed of the same material including, for example, high-k dielectric material. In addition, the first high-k dielectric layer 180A and the first insulation layer 160A may be formed in different processes. Similarly, the second high-k dielectric layer 180B and the second insulation layer 160B may be formed in different processes.

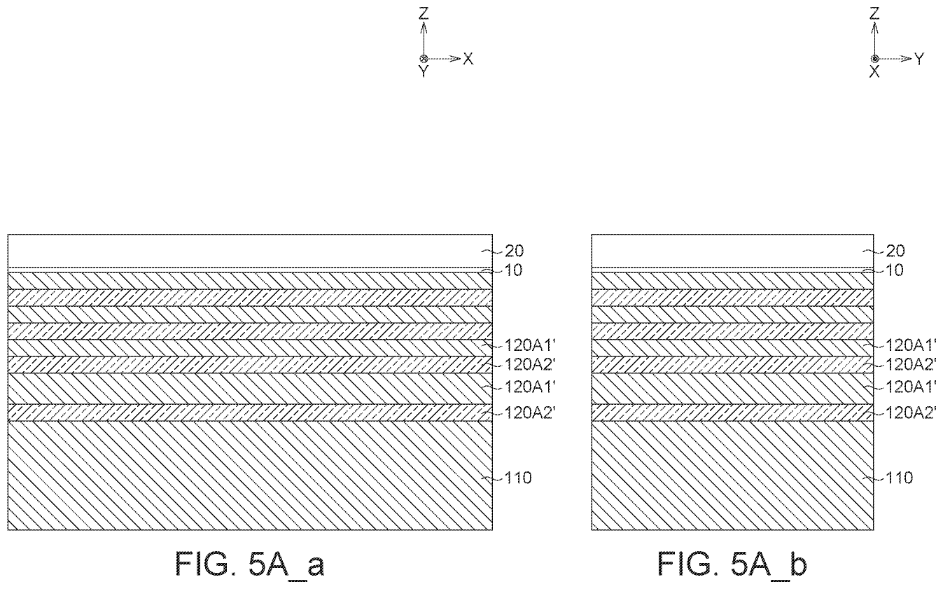

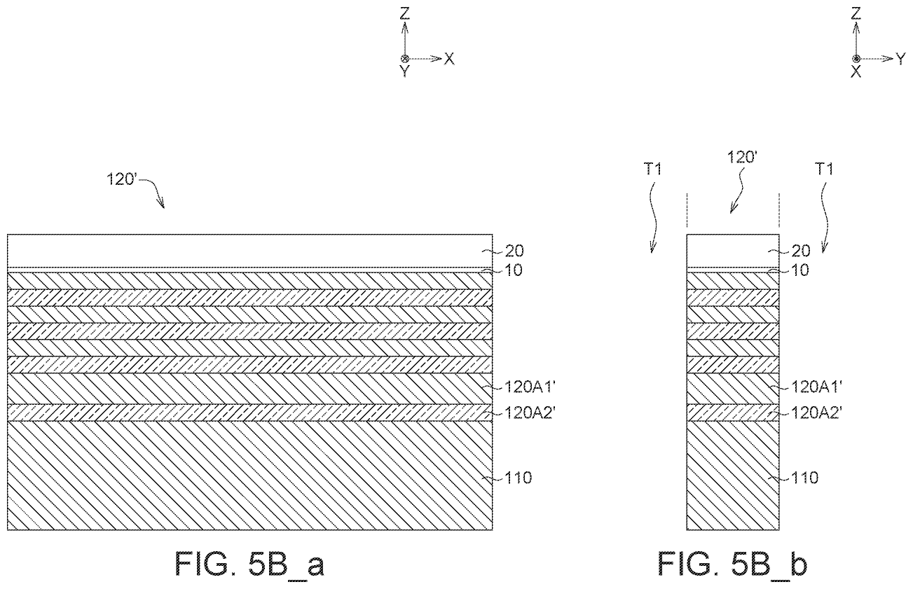

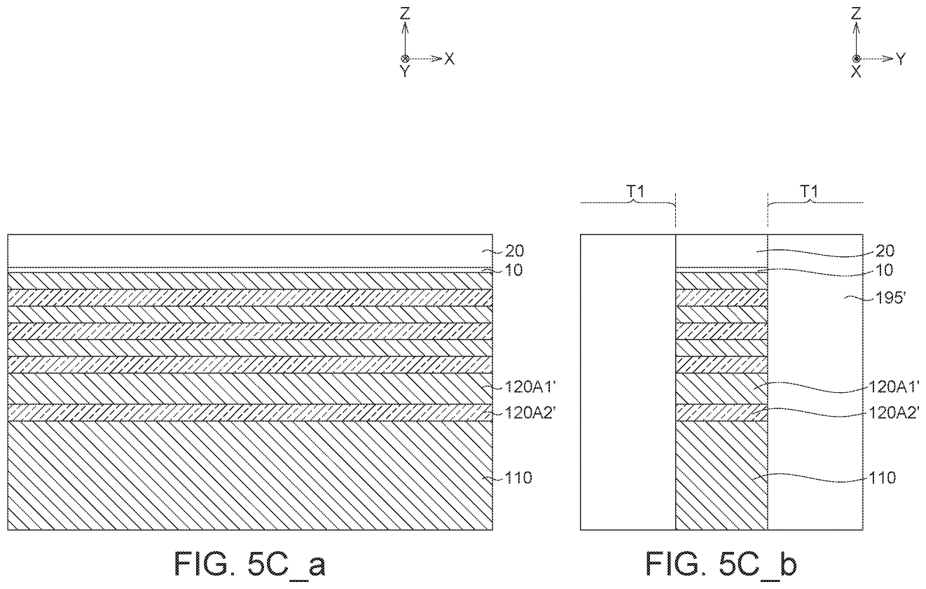

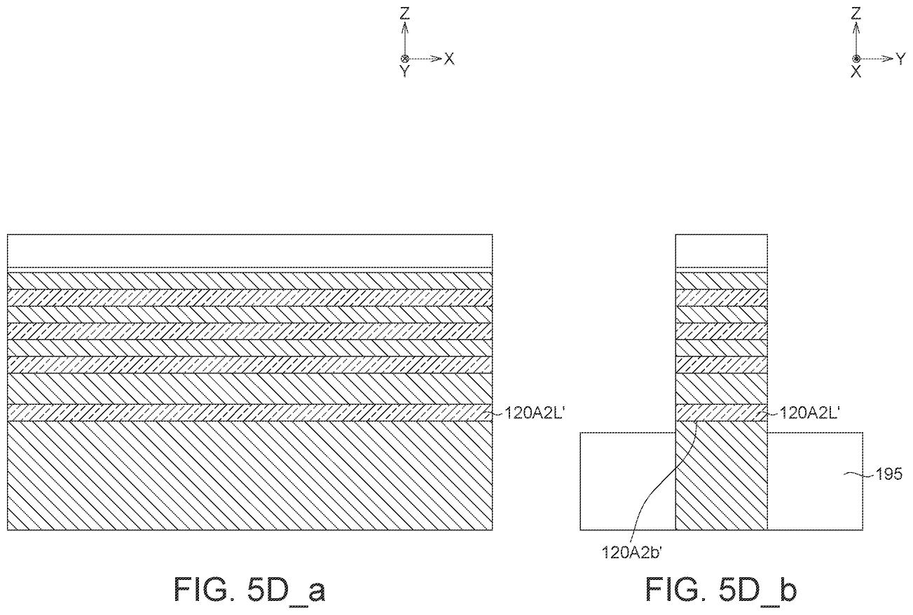

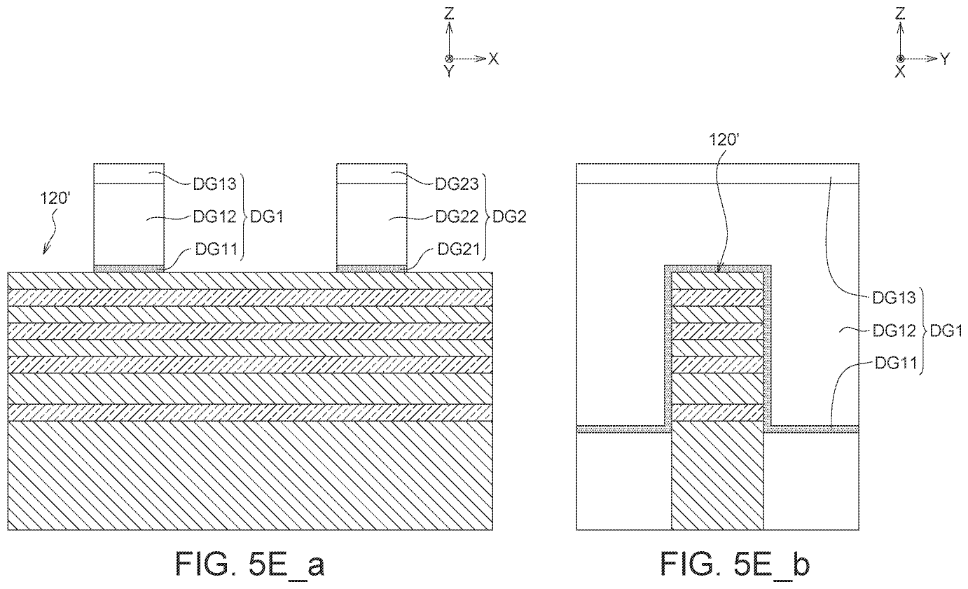

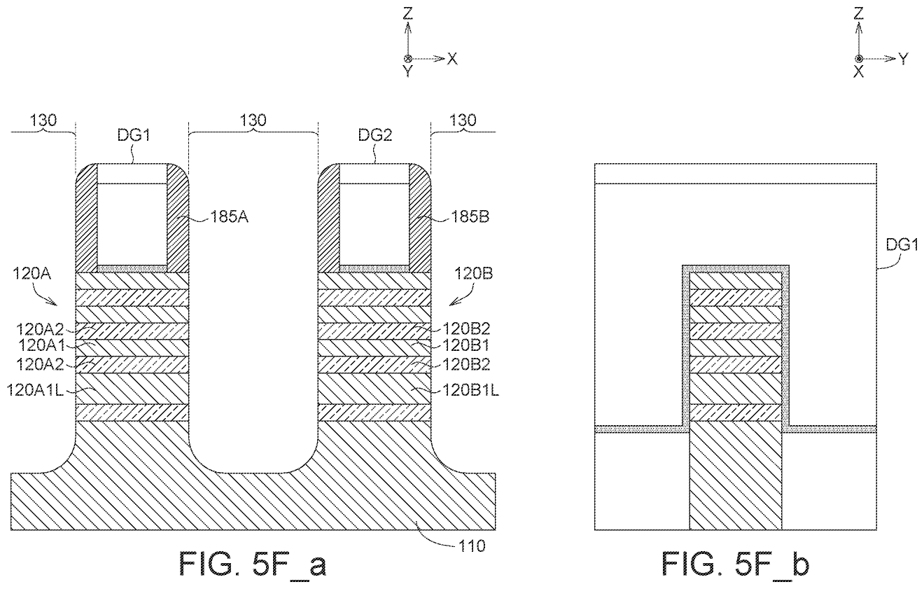

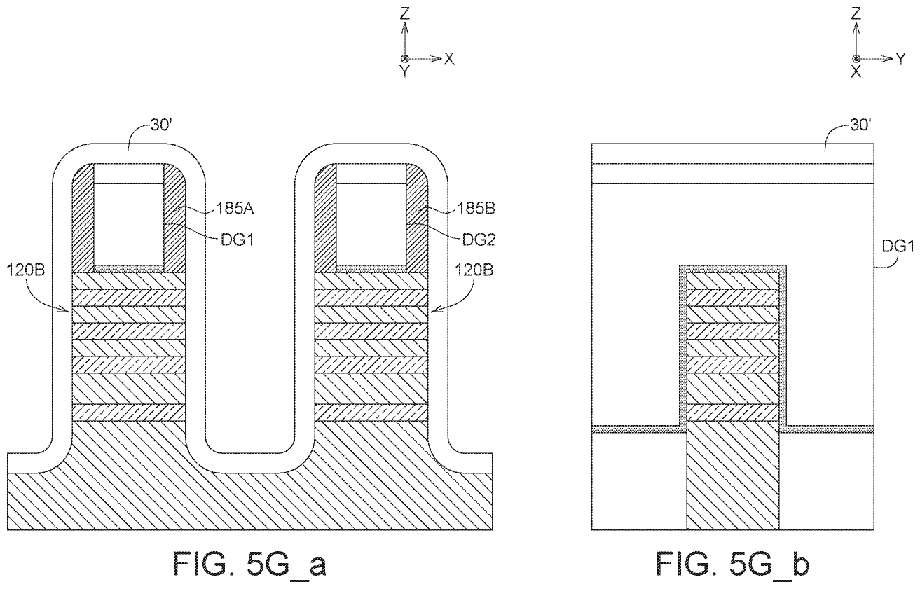

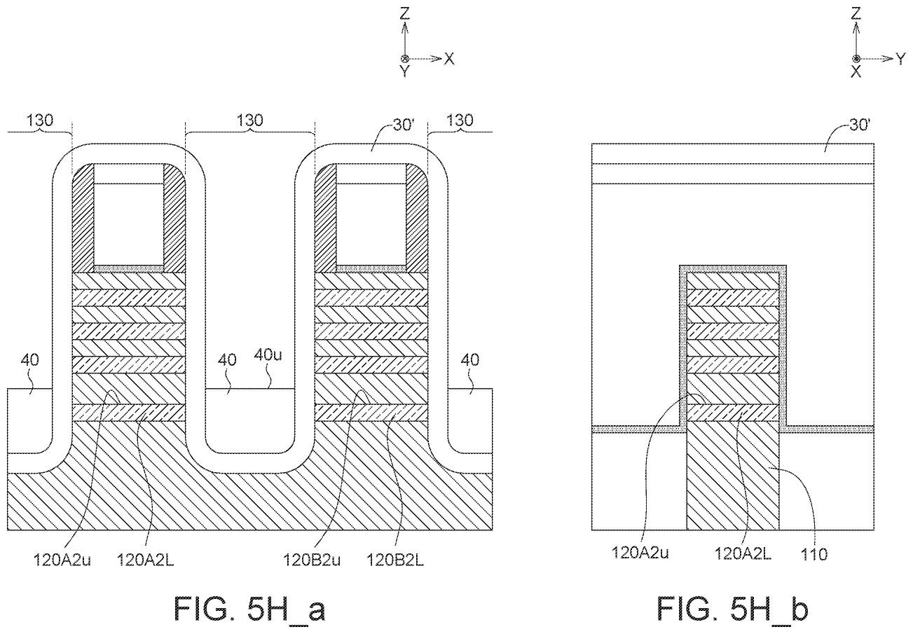

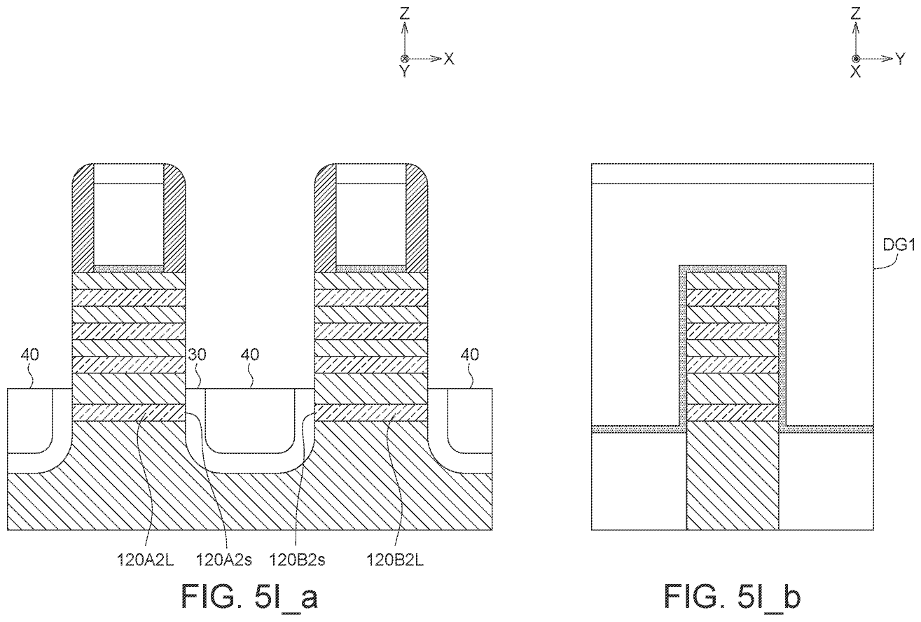

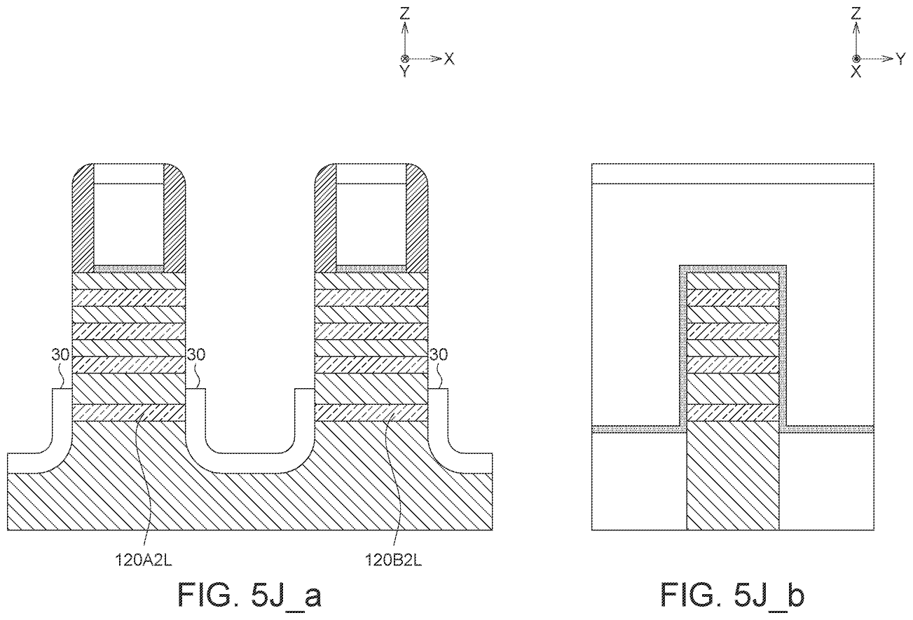

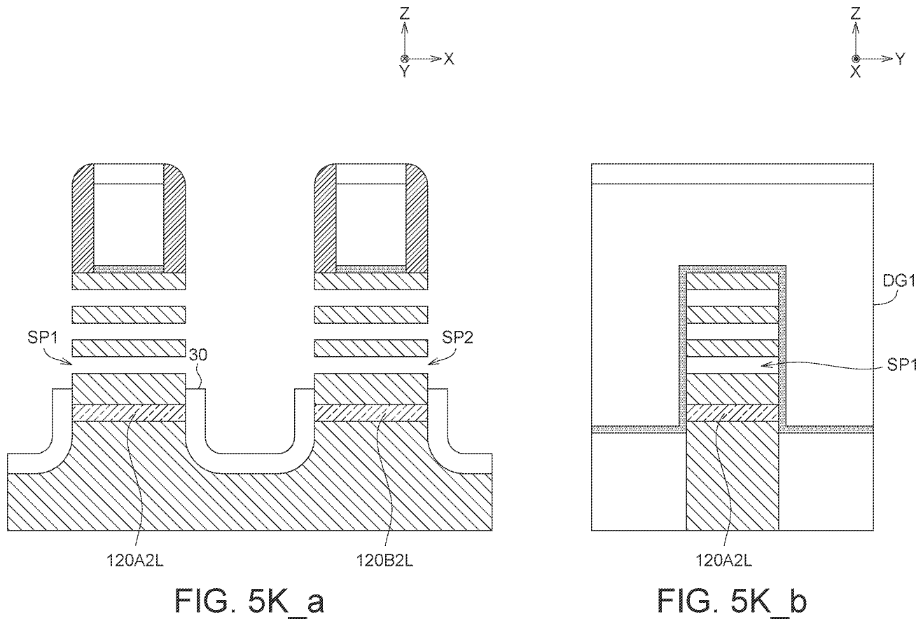

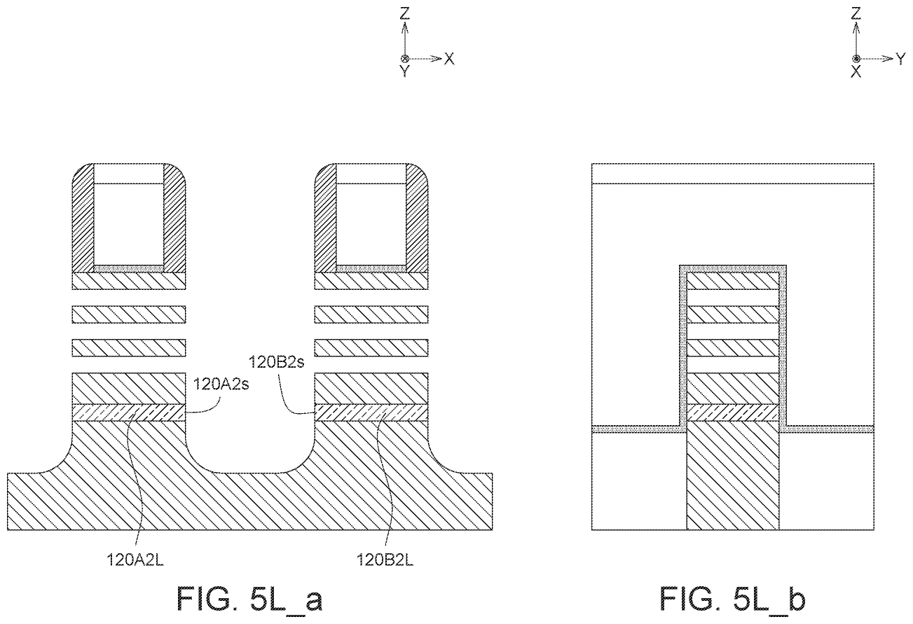

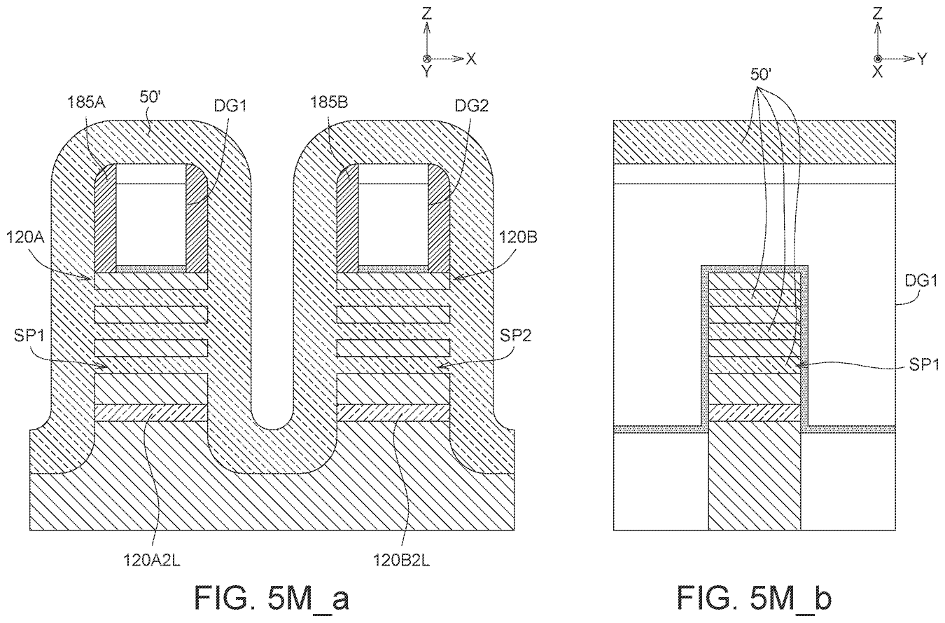

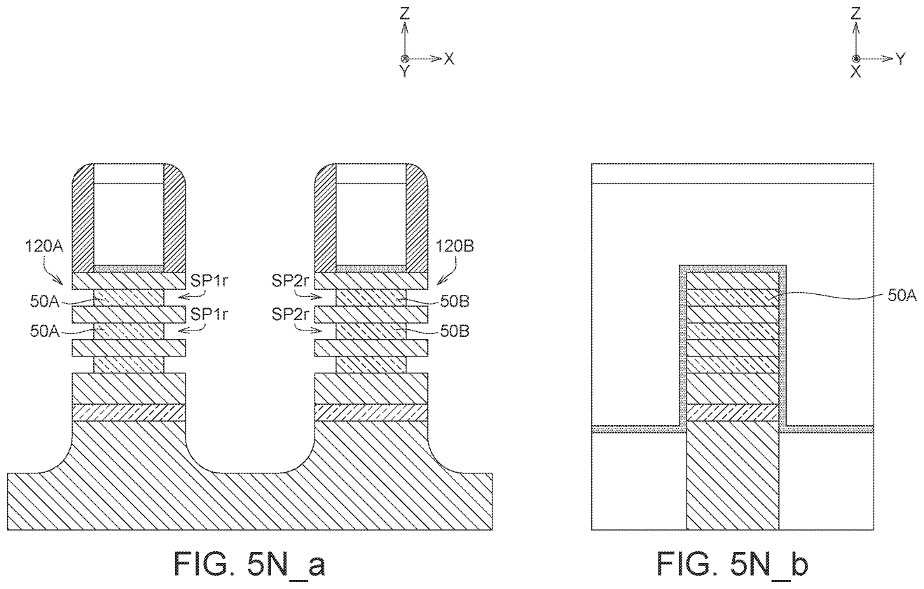

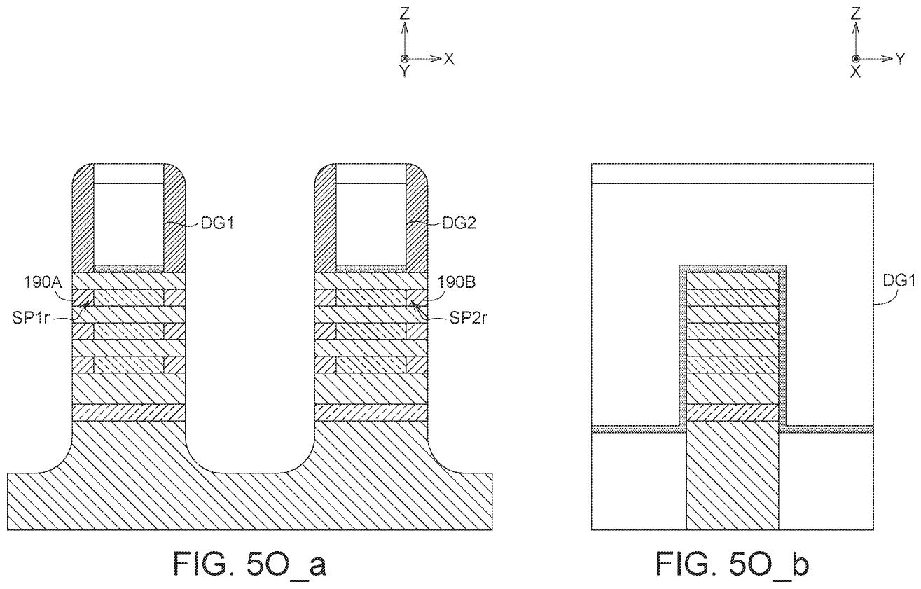

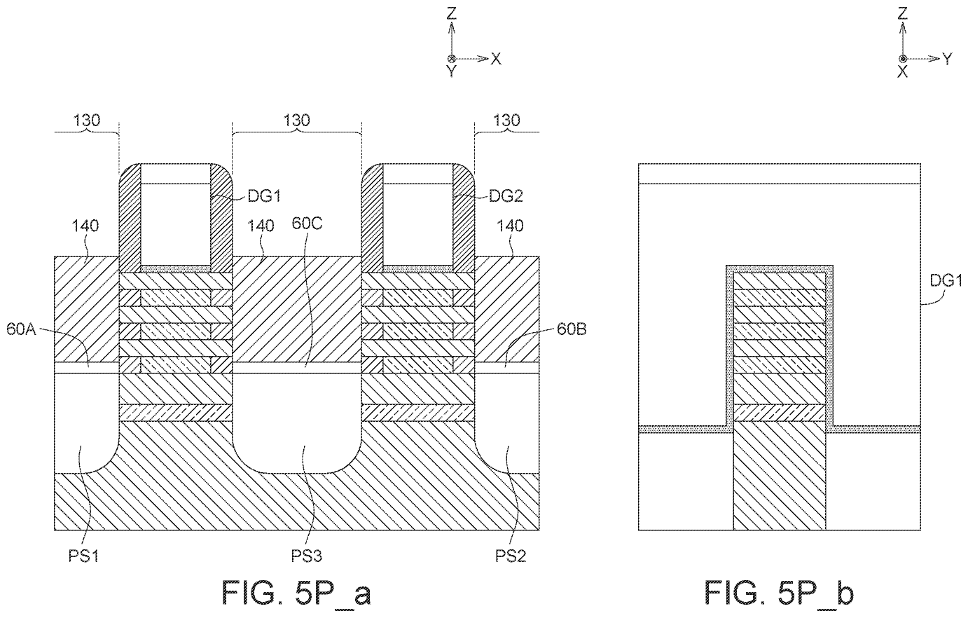

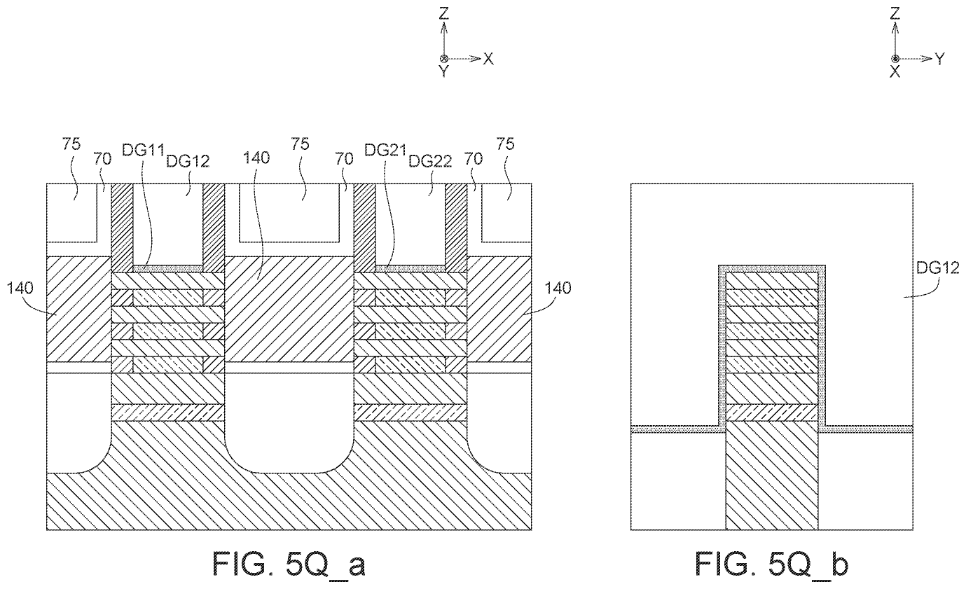

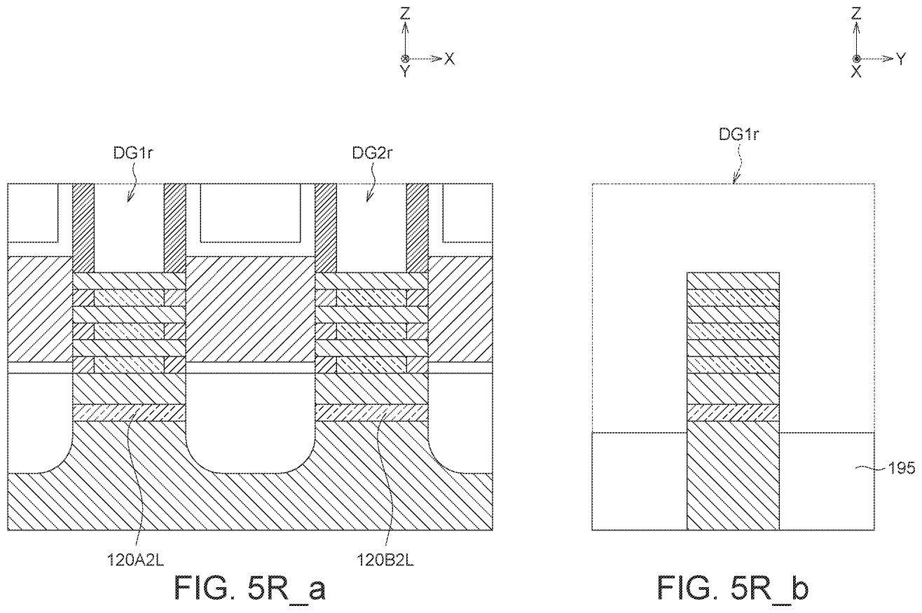

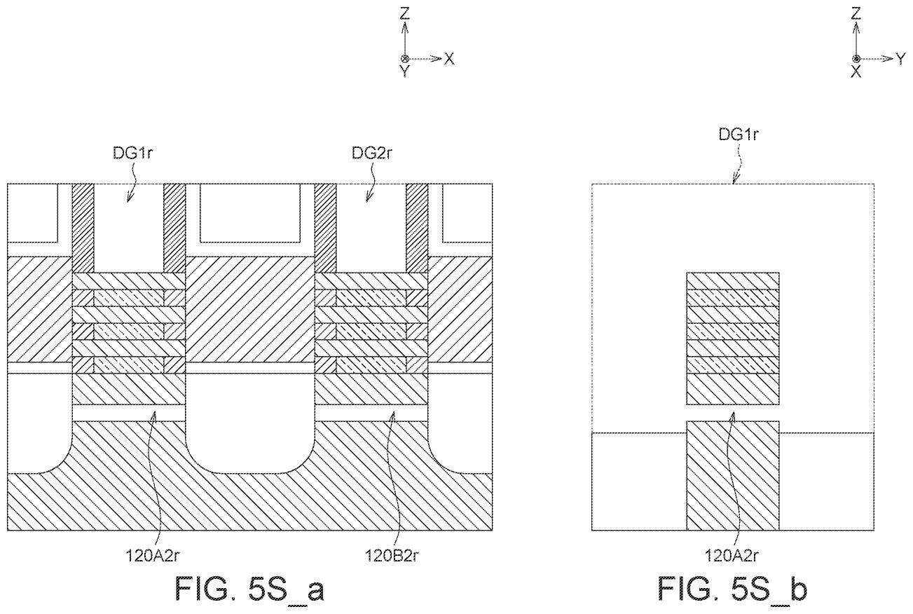

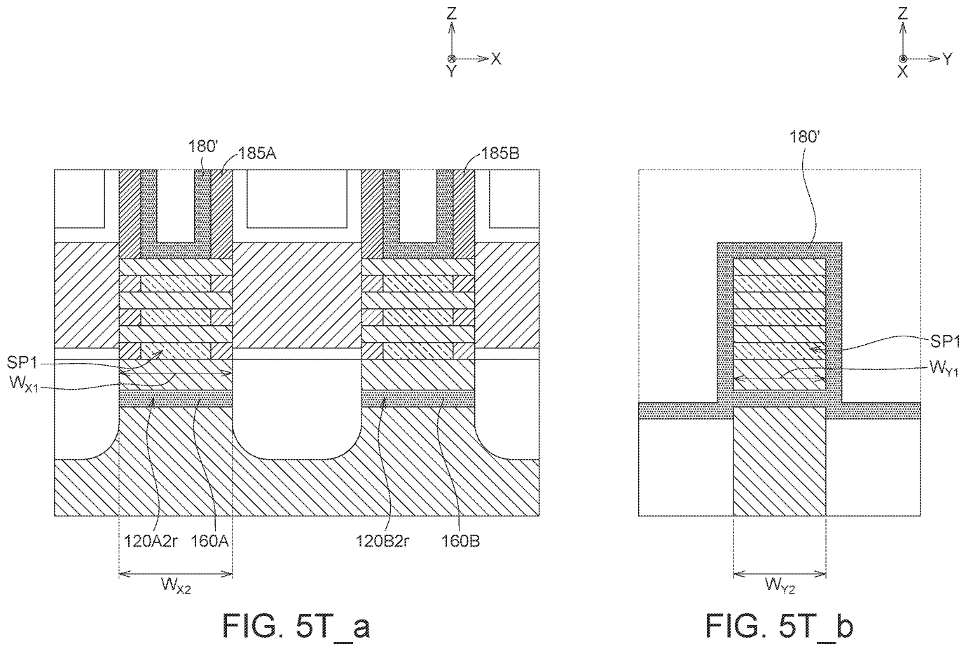

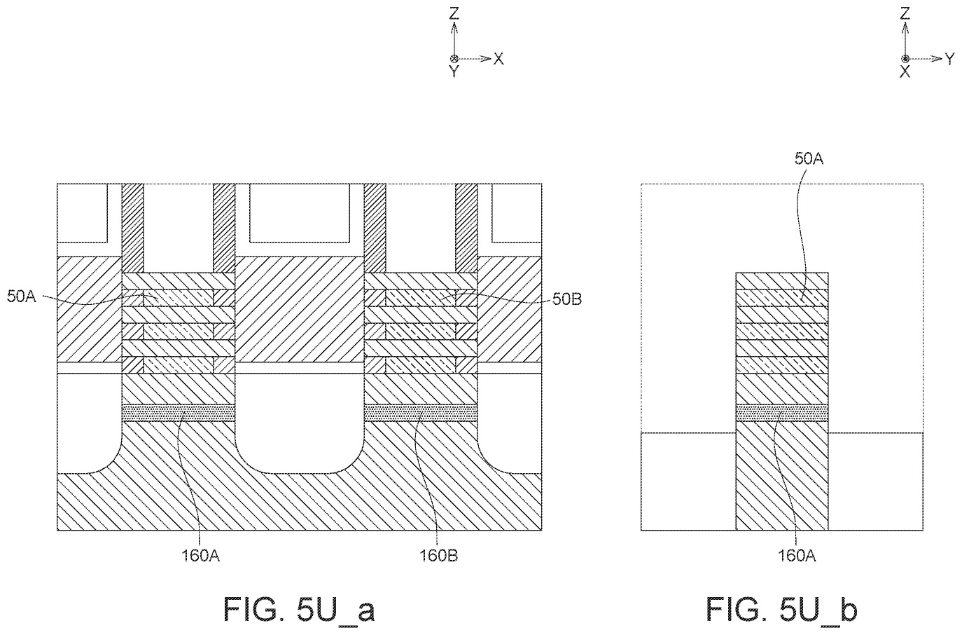

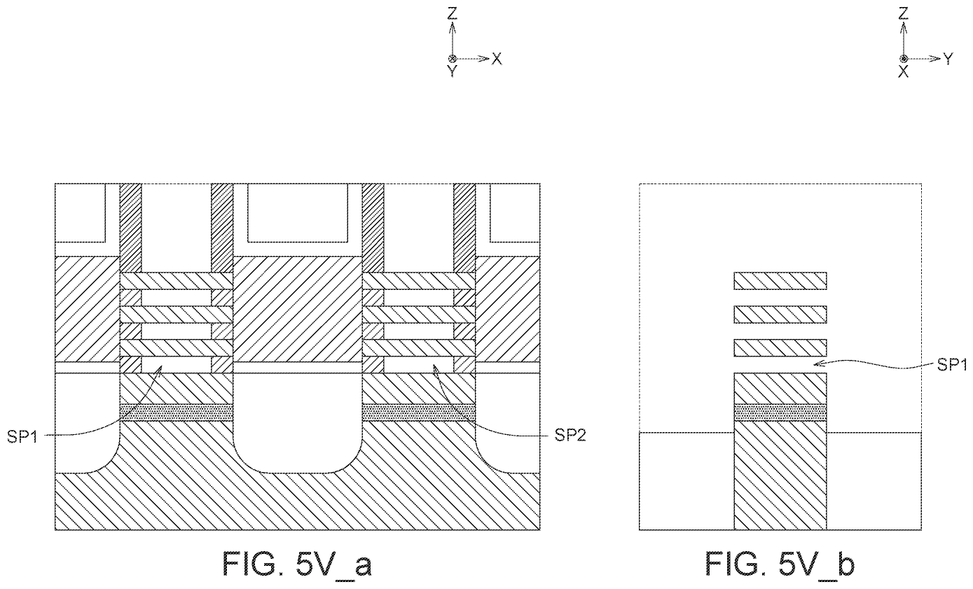

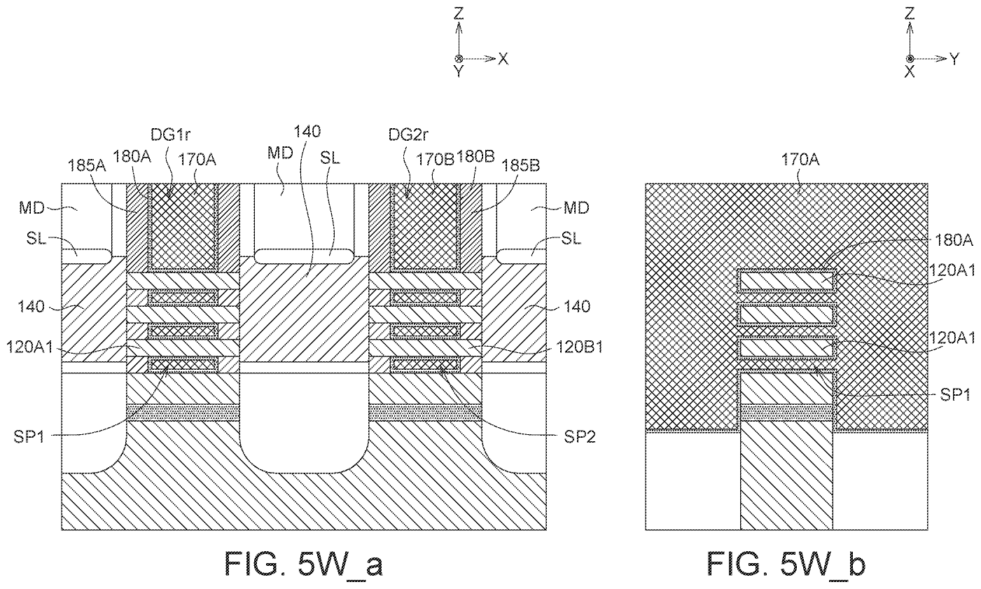

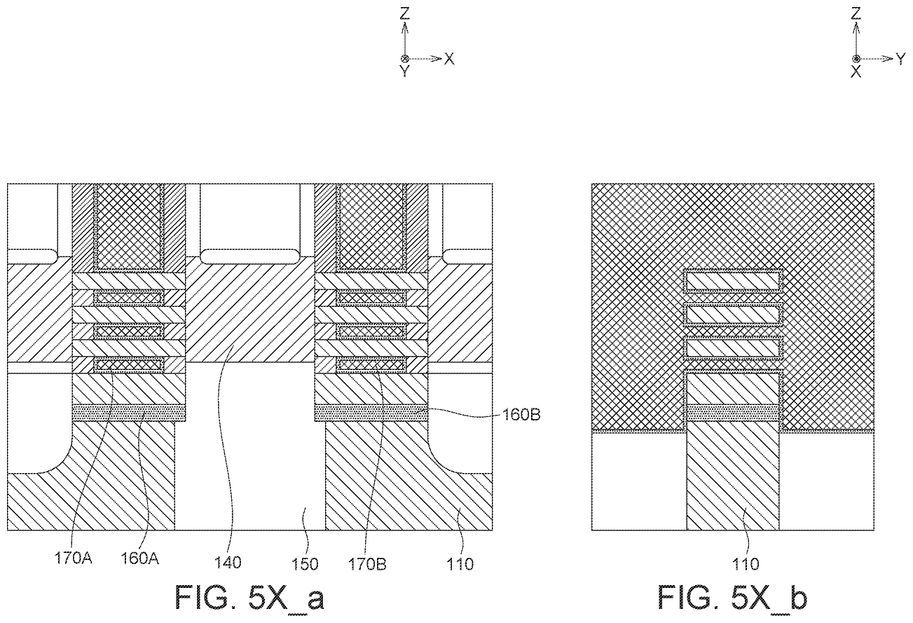

FIGS. 5A_a to 5X_b illustrate schematic diagrams of manufacturing processes of the semiconductor device 100 of FIGS. 1a and 1b.

As illustrated in FIGS. 5A_a and 5A_b, a plurality of sheet layers 120A1′ and a plurality of spacer layers 120A2′ are stacked on the substrate 110, wherein one spacer layer 120A2′ is formed between the adjacent two sheet layer 120A1′. Then, a pad oxide layer 10 and a hard mask 20 are formed over the stack structure of the sheet layers 120A1′ and the spacer layers 120A2′. The spacer layer may be formed of a material including, for example, silicon germanium (SiGe), and the sheet layer may be formed of a material including, for example, silicon.

As illustrated in FIGS. 5B_a and 5B_b, a portion of each sheet layer 120A1′ and a portion of each spacer layer 120A2′ are removed to form at least one interval through the patterned pad oxide layer 10 and hard mask 20 T1 by using, for example, etching, etc. A remaining portion of each sheet layer 120A1′, a remaining portion of each spacer layer 120A2′ form at least one fin structure 120′ in the first direction (for example, X axis). The region of one fin structure 120′ defines one OD region, for example.

As illustrated in FIGS. 5C_a and 5C_b, at least one oxide layer material 195′ is formed within the intervals T1 by using, for example, deposition, etc. Then, the pad oxide layer 10, the hard mask 20 and a portion of the oxide layer material 195′ are removed by a Chemical-Mechanical Polishing (CMP), etc.

As illustrated in FIGS. 5D_a and 5D_b, a portion of the oxide layer material 195′ is removed to form the oxide layer 195 by, for example, etching, etc. The oxide layer 195 is lower than the lowermost spacer layer 120A2L′. For example, the oxide layer 195 is lower than a lower surface 120A2b′ of the lowermost spacer layer 120A2L′. As a result, the lowermost spacer layer 120A2L′ could be fully or completely removed in subsequent process. Then, the pad oxide layer 10 and the hard mask 20 are removed by, for example, etching or CMP.

As illustrated in FIGS. 5E_a and 5E_b, a patterned first dummy gate structure DG1 is formed on the fin structure 120′. The first dummy gate structure DG1 includes an oxide layer DG11, a dummy gate layer DG12 and a mask layer DG13. The oxide layer DG11 is formed on the fin structures 120′ and the oxide layer 195. The dummy gate layer DG12 is formed over the oxide layer DG11, and the mask layer DG13 is formed over the dummy gate layer DG12. In an embodiment, the dummy gate layer DG12 may be deposited over the oxide layer DG11 and then planarized, such as by CMP, and then the mask layer DG13 may be deposited over the dummy gate layer DG12.

Similarly, a patterned second dummy gate structure DG2 is formed on the fin structure 120′. The second dummy gate structure DG2 includes an oxide layer DG21, a dummy gate layer DG22 and a mask layer DG23. The oxide layer DG21 is formed on the fin structures 120′ and the oxide layer 195. The dummy gate layer DG22 is formed over the oxide layer DG21, and the mask layer DG23 is formed over the dummy gate layer DG22. In an embodiment, the dummy gate layer DG22 may be deposited over the oxide layer DG21 and then planarized, such as by CMP, and then the mask layer DG23 may be deposited over the dummy gate layer DG22.

The dummy gate layer may be a conductive or non-conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer may be deposited by physical vapor deposition (PVD), CVD, sputter deposition, or other techniques for depositing the selected material. The dummy gate layer may be formed of other materials that have a high etching selectivity from the etching of isolation regions. The mask layer may include, for example, silicon nitride, silicon oxynitride, or the like.

As illustrated in FIGS. 5F_a and 5F_b, the first spacer layer 185A over a lateral surface of the first dummy gate structure DG1 and the second spacer layer 185B over a lateral surface of the second dummy gate structure DG2 are formed by, for example, deposition, etc. Then, a portion of the fin structure 120′ is removed to form at least one active structure (at least include the first active structure 120A and the second active structure 120B) by, for example, anisotropic etching such as global SSD (GSSD) etching, etc. There are a plurality of the trenches formed a plurality of the active structures. For example, there is one trench 130 formed between the first active structure 120A and the second active structure 120B. The first active structure 120A includes a plurality of the sheets 120A1 and a plurality of the spacers 120A2, wherein one spacer 120A2 is formed between the adjacent two sheets 120A1. The second active structure 120B includes a plurality of the sheets 120B1 and a plurality of the spacers 120B2, wherein one spacer 120B2 is formed between the adjacent two sheets 120B1.

As illustrated in FIGS. 5G_a and 5G_b, a hard mask layer 30′ over the first dummy gate structure DG1, the second dummy gate structure DG2, the first spacer layer 185A, the second spacer layer 185B, the first active structure 120A and the second active structure 120B is formed by, for example, deposition, etc. The hard mask layer 30′ may be formed of a material including, for example, AlOx, etc.

As illustrated in FIGS. 5H_a and 5H_b, a block material over the hard mask layer 30′ is formed by, for example, coating, deposition, spinning, etc., and then a portion of the block material is removed to form at least one block 40 within the bottom of the trench 130 by etching back, etc. The block 40 has an upper surface 40u higher than the lowermost spacer 120A2L and the lowermost spacer layers 120B2L. For example, the upper surface 40u of the block 40 is higher than an upper surface 120A2u of the lowermost spacer 120A2L and an upper surface 120B2u of the lowermost spacer 120B2L.

As illustrated in FIGS. 5I_a and 5I_b, a portion of the hard mask layer 30′ is removed to form at least one hard mask 30 by, for example, etching back, etc. The hard mask 30 is retained during etching due to the blocking of the block 40. The hard mask 30 covers a lateral surface 120A2s of the lowermost spacer 120A2L and a lateral surface of the lowermost spacer 120B2L. As a result, the lowermost spacer 120A2L and the lowermost spacer 120B2L are not removed in the subsequent process, for example, process shown in FIGS. 5K_a and 5K_b.

As illustrated in FIGS. 5J_a and 5J_b, the blocks 40 are removed to expose the hard mask 30 by, for example, etching, etc.

As illustrated in FIGS. 5K_a and 5K_b, the spacers 120A2 and the spacers 120B2 of FIG. 5J_a which are not covered by the hard mask 30 are removed to form the first spaces SP1 and the second spaces SP2 by, for example, dry etching, etc. The lowermost spacers 120A2L and 120B2L are retained due to the blocking of the hard mask 30.

As illustrated in FIGS. 5L_a and 5L_b, the hard mask 30 of FIG. 5K_a is removed to expose the lateral surface 120A2s of the lowermost spacer 120A2L and the lateral surface 120B2s of the lowermost spacer 120B2L by, for example, etching, etc.

As illustrated in FIGS. 5M_a and 5M_b, an oxide material 50′ over the first active structure 120A, the second active structure 120B, the first dummy gate structure DG1, the second dummy gate structure DG2, the first spacer layer 185A, the second spacer layer 185B, the lowermost spacer 120A2L and the lowermost spacer 120B2L is formed by, for example, ALD (atomic layer deposition), FCVD (Flowable CVD) or a combination thereof. The oxide material 50′ fills the first spaces SP1 of the first active structure 120A and the second spaces SP2 of the second active structure 120B.

As illustrated in FIGS. 5N_a and 5N_b, a portion of the oxide material 50′ of FIG. 5M_a is removed to form a plurality of first oxide spacers 50A within the first spaces SP1 of the first active structure 120A and a plurality of second oxide spacers 50B within the second spaces SP2 of the second active structure 120B. The first oxide spacer 50A is recessed with respect to a lateral surface of the sheet to form a first recess SP1r, and the second oxide spacer 50B is recessed with respect to a lateral surface of the sheet to form a second recess SP2r.

As illustrated in FIGS. 5O_a and 5O_b, a plurality of the first inner spacers 190A within the first recesses SP1r and a plurality of the second inner spacers 190B within the second recesses SP2r are formed by, for example, depiction, etching back, etc.

As illustrated in FIGS. 5P_a and 5P_b, a pure silicon layer, a block layer and at least one epitaxy 140 are formed. The pure silicon layer is formed within the bottom of each trench 130 by, for example, epitaxy process, the block layer is formed over the pure silicon layer, and the epitaxy 140 is formed over the block layer. Furthermore, the pure silicon layer includes the first pure silicon layer PS1, the second pure silicon layer PS2 and a third pure silicon layer PS3, wherein the third pure silicon layer PS3 is formed within the trench 130 between the first active structure 120A and the second active structure 120B, the first pure silicon layer PS1 and the third pure silicon layer PS3 are located at two opposite sides of the first active structure 120A, and the second pure silicon layer PS2 the third pure silicon layer PS3 are located at two opposite sides of the second active structure 120B. The block layer includes a first block layer 60A, a second block layer 60B and a third block layer 60C, wherein the first block layer 60A is formed over the first pure silicon layer PS1, the second block layer 60B is formed over the second pure silicon layer PS2, and the third block layer 60C is formed over the third pure silicon layer PS3. The block layer may be formed of a material including, nitride, etc.

As illustrated in FIGS. 5Q_a and 5Q_b, a portion of the structure of FIGS. 5P_a and 5P_b is removed by, for example, CMP. Furthermore, the mask layer DG13 and DG23 are removed.

As illustrated in FIGS. 5Q_a and 5Q_b, a bottom CESL (BCESL) layer 70 is formed over the epitaxies 140 by using, for example, deposition, such as CVD, PECVD, ALD, or the like. The bottom CESL 70 may be formed of a material including, for example, a dielectric material, such as silicon nitride, silicon oxide, silicon oxynitride, or the like. Then, a ILD layer 75 covering the bottom CESL layer 70 is formed by using, for example, deposition, such as CVD, PECVD, or FCVD, or the like. In addition, the ILD layer 75 may be planarized by, for example, CMP, etc. The ILD layer 75 may be formed of a dielectric including, for example, PSG, BSG, BPSG, USG, or the like. Other insulation materials formed by any acceptable process may be used.

As illustrated in FIGS. 5R_a and 5R_b, the oxide layer DG11 and dummy gate layer DG12 of the first dummy gate structure DG1 and the oxide layer DG21 and dummy gate layer DG22 of the second dummy gate structure DG2 in FIG. 5Q_a are removed to form a first recess DG1r and the second recess DG2r respectively by, for example, dry etching, etc. After removal of the oxide layer DG11, the active structures (for example, the first active structure 120A and the second active structure 120B) are exposed.

As illustrated in FIGS. 5S_a and 5S_b, the lowermost spacer 120A2L and the lowermost spacer 120B2L are removed to form the lowermost first space 120A2r and the lowermost second space 120B2r by dry etching, etc.

As illustrated in FIGS. 5T_a and 5T_b, a high-K layer material 180′ over the first spacer layer 185A and the second spacer layer 185B and within the lowermost first space 120A2r and the lowermost second space 120B2r is formed by, for example, ALD, etc. A portion of the high-K layer material 180′ forms the first insulation layer 160A within the lowermost first space 120A2r and the second insulation layer 160B within the lowermost second space 120B2r. In addition, the first space SP1 has a first width Wx1 in the first direction (for example, X axis), and the first insulation layer 160A has a second width Wx2 in the first direction), wherein the first width Wx1 is substantially equal to the second width Wx2. The first space SP1 has a first width W_{Y1} in the second direction (for example, Y axis), and the first insulation layer 160A has a second width W_{Y2} in the second direction), wherein the first width W_{Y1} is substantially equal to the second width W_{Y2}. The second space SP2 and the first insulation layer 160B has the features the same as or similar to that of the first space SP1 and the first insulation layer 160A, and it will not be repeated here.

As illustrated in FIGS. 5U_a and 5U_b, a portion of the high-K layer material 180′ is removed, but the first insulation layer 160A and the second insulation layer 160B are retained.

As illustrated in FIGS. 5V_a and 5V_b, the first oxide spacers 50A and the second oxide spacers 50B in FIGS. 5U_a and 5U_b are removed to form a plurality of the first spaces SP1 and a plurality of the second spaces SP2 by, for example, dry etching, etc.

As illustrated in FIGS. 5W_a and 5W_b, the first high-k dielectric layer 180A covering the sheets 120A1 and the first spacer layer 185A is formed by, for example, ALD, etc. and the second high-k dielectric layer 180B covering the sheets 120B1 and the second spacer layer 185B is formed by, for example, ALD, etc. Then, the first metal gate 170A within the first recess DG1r and the first spaces SP1 and the second metal gate 170B within the second recess DG2r and the second spaces SP2 are formed. Then, at least one silicide layer SL is formed on the epitaxy 140, and at least one metal over diffusion MD is formed over the silicide layer SL.

As illustrated in FIGS. 5X_a and 5X_b, the back-side conductive via 150 passing through the substrate 110 is formed to connect the epitaxy 140 by in the SPR SAC process. The first insulation layer 160A could block the back-side conductive via 150 from being in contact with the first metal gate 170A, and the second insulation layer 160B could block the back-side conductive via 150 from being in contact with the second metal gate 170B.

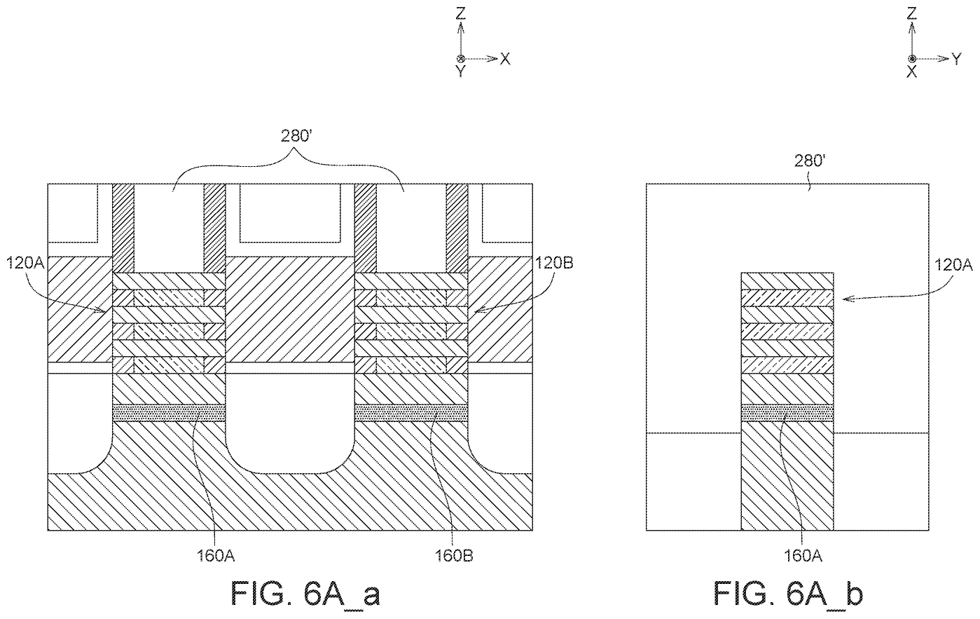

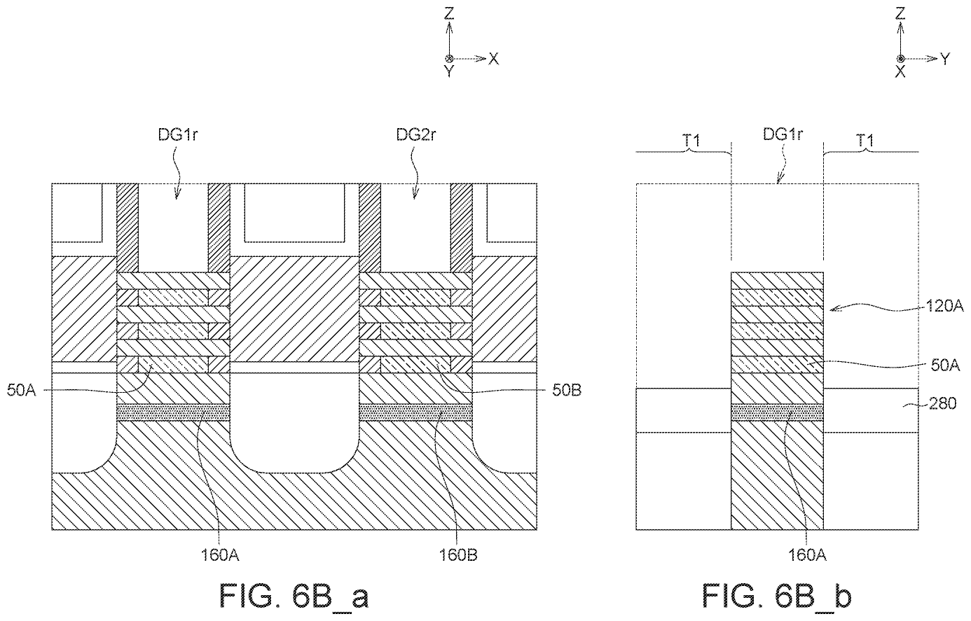

FIGS. 6A_a to 6B_b illustrate schematic diagrams of manufacturing processes of the semiconductor device 200 of FIGS. 2a and 2b.

The manufacturing processes of the semiconductor device 200 includes the processes the same as or similar to processes of the semiconductor device 100 shown in FIGS. 5A_a to 5R_b.

Then, as illustrated in FIGS. 6A_a and 6A_b, a cushion layer material 280′ over the first active structure 120A and the second active structure 120B is formed by, for example, refilling, etc. The cushion layer material 280′ may be formed of a material including, for example, a low-K material, such as SICO, SiON, SiCON, etc.

As illustrated in FIGS. 6B_a and 6B_b, a portion of the cushion layer material 280′ is removed to form at least one cushion layer 280 by, for example, etching back, etc. The cushion layers 280 are formed within the intervals T1, located at two opposite sides of the first active structure 120A and located at two opposite sides of the second active structure 120B (not shown). In the present embodiment, the cushion layer 280 is lower than the first oxide spacers 50A and the second oxide spacers 50B, but higher than the first insulation layer 160A and the second insulation layer 160.

Then, the follow-up processes for the semiconductor device 200 are the same as or similar to that of the semiconductor device 100, for example, the processes shown in FIGS. 5V_a to 5X_b.

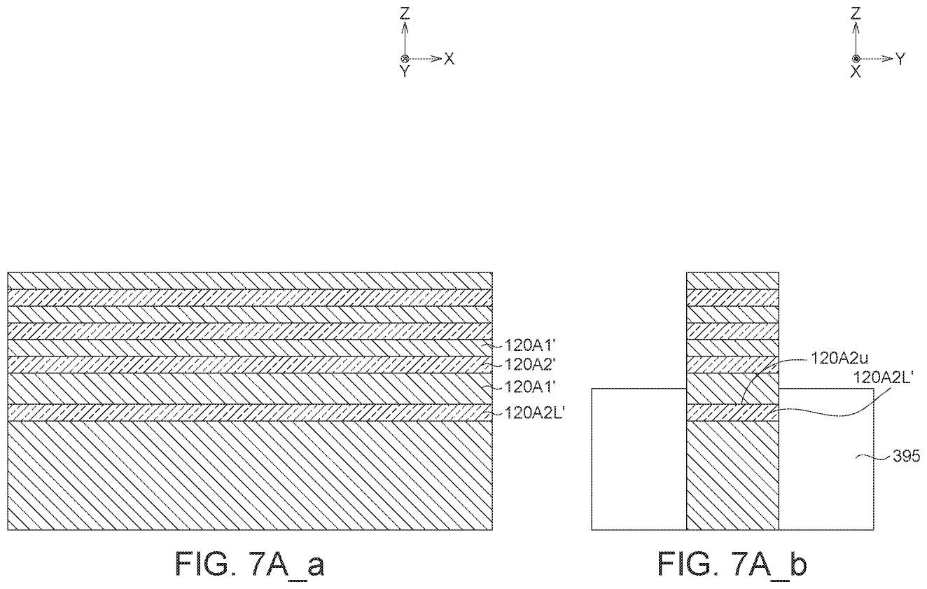

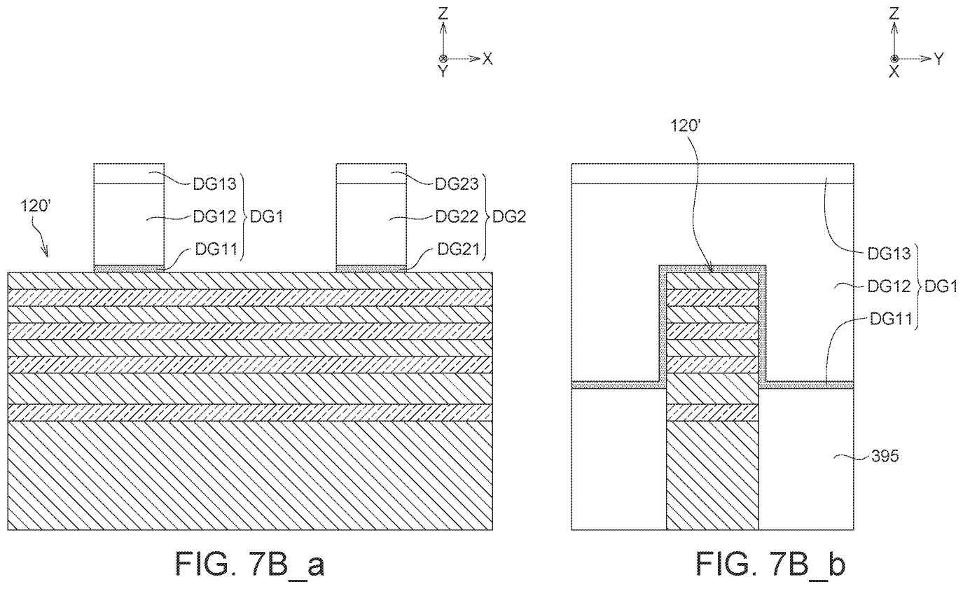

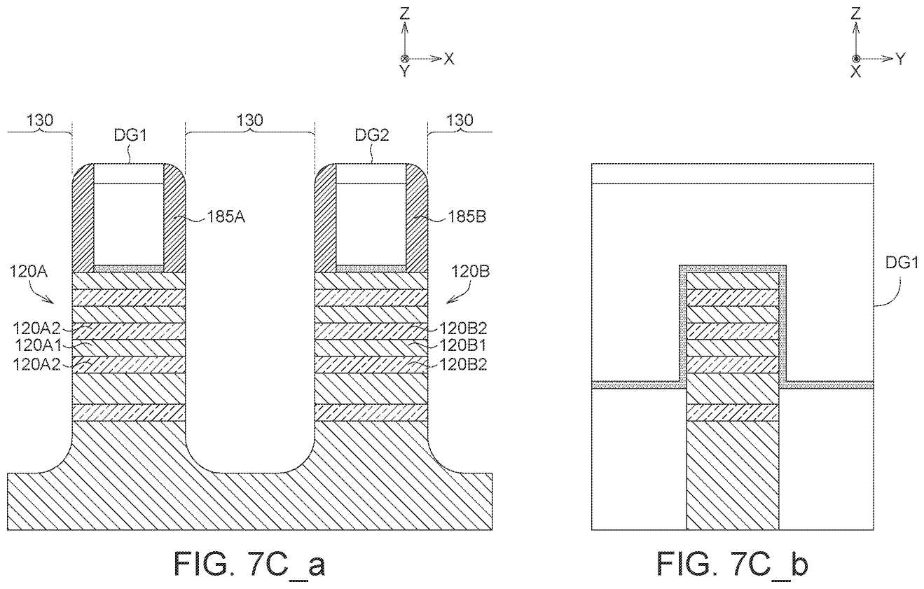

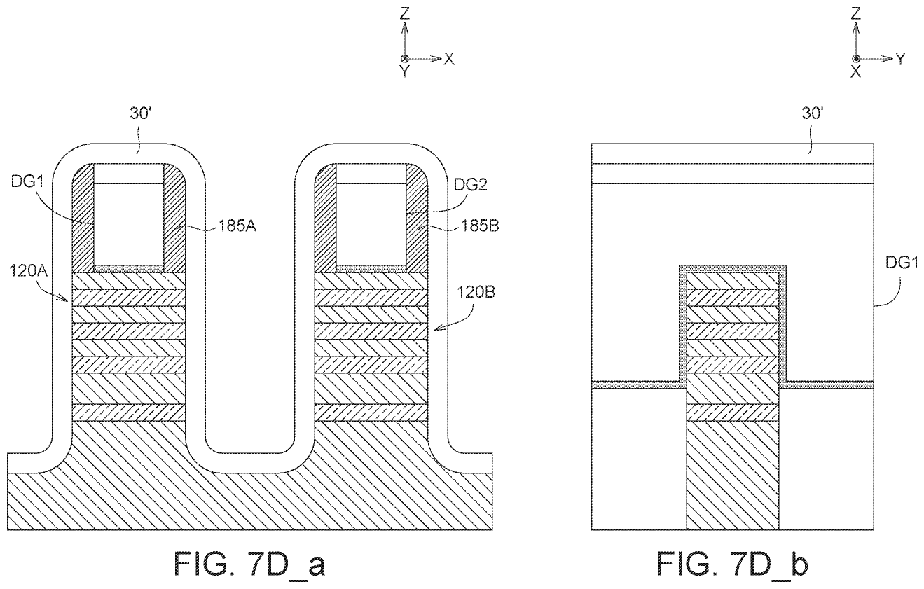

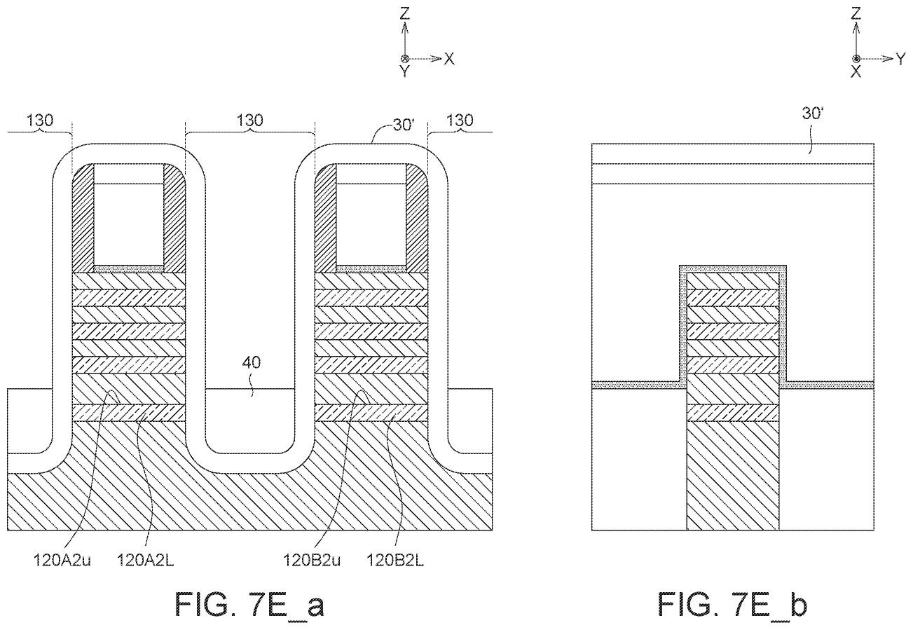

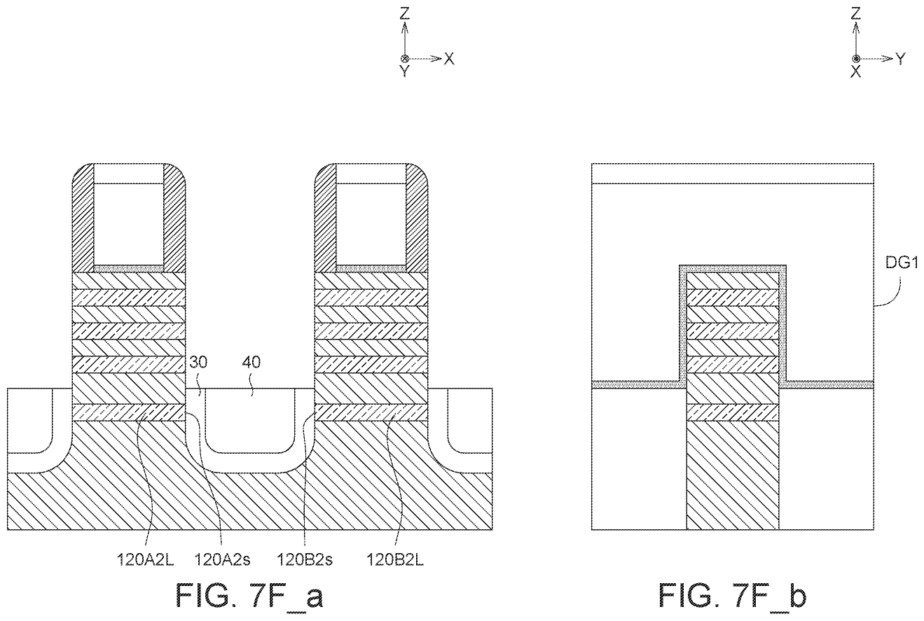

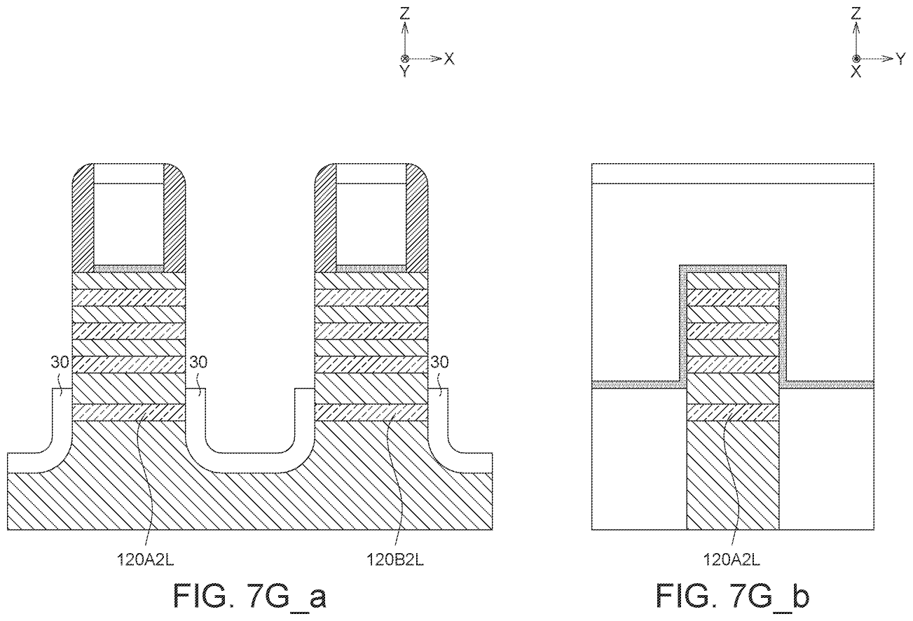

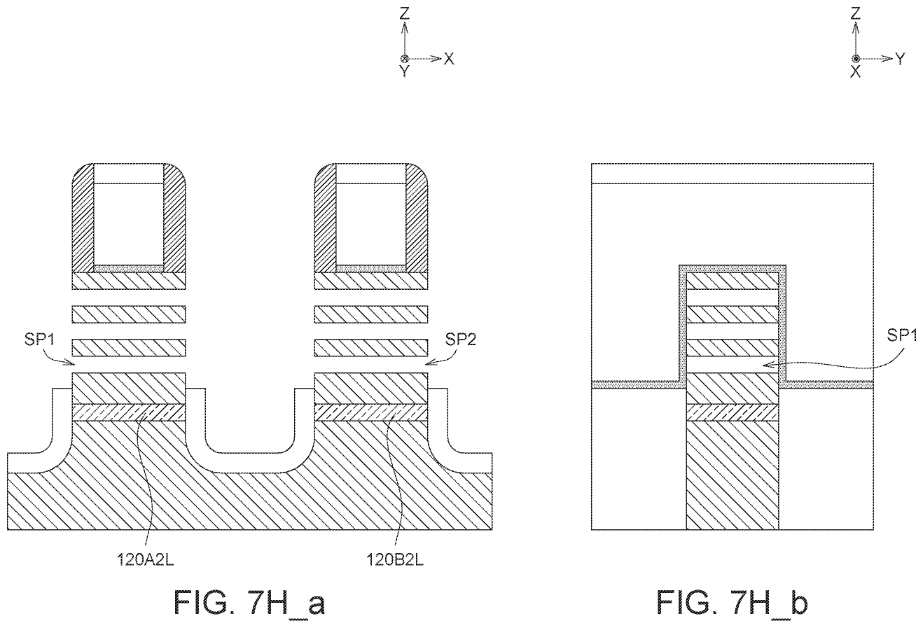

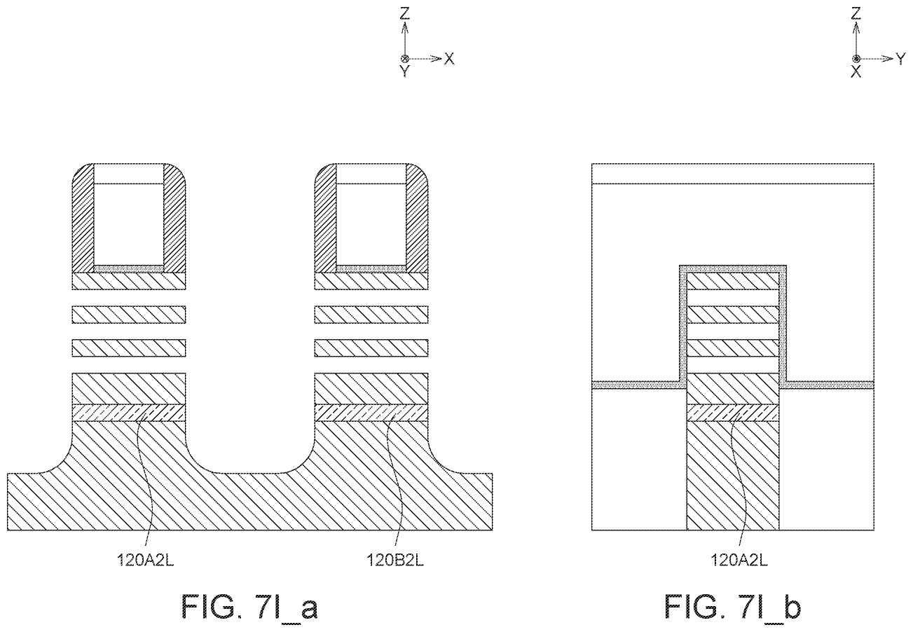

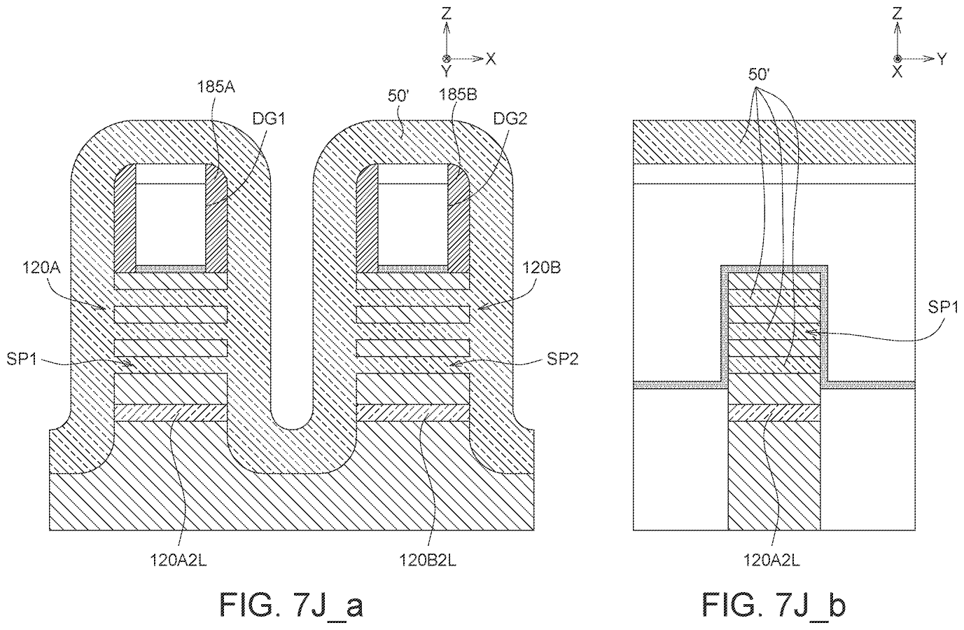

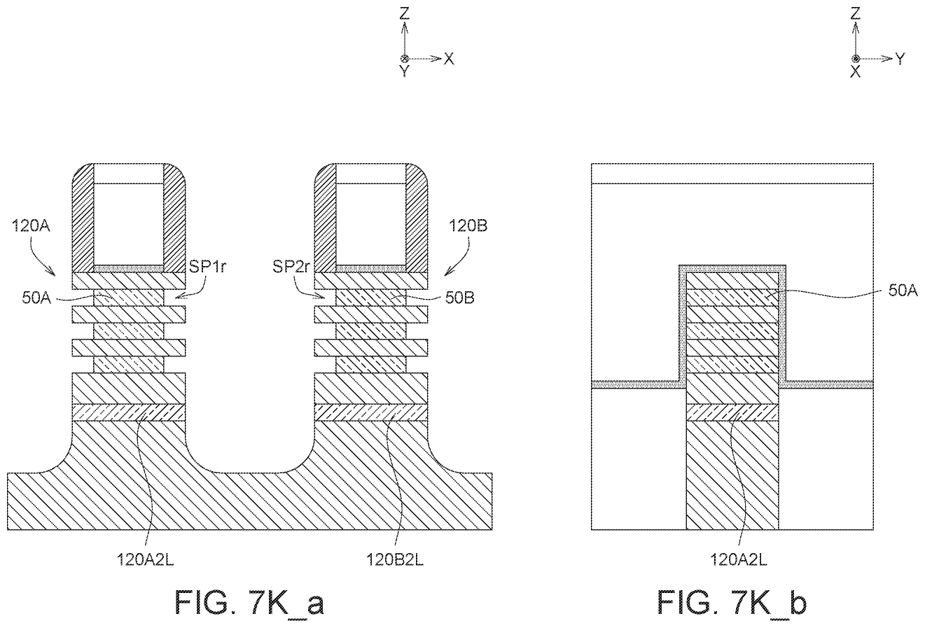

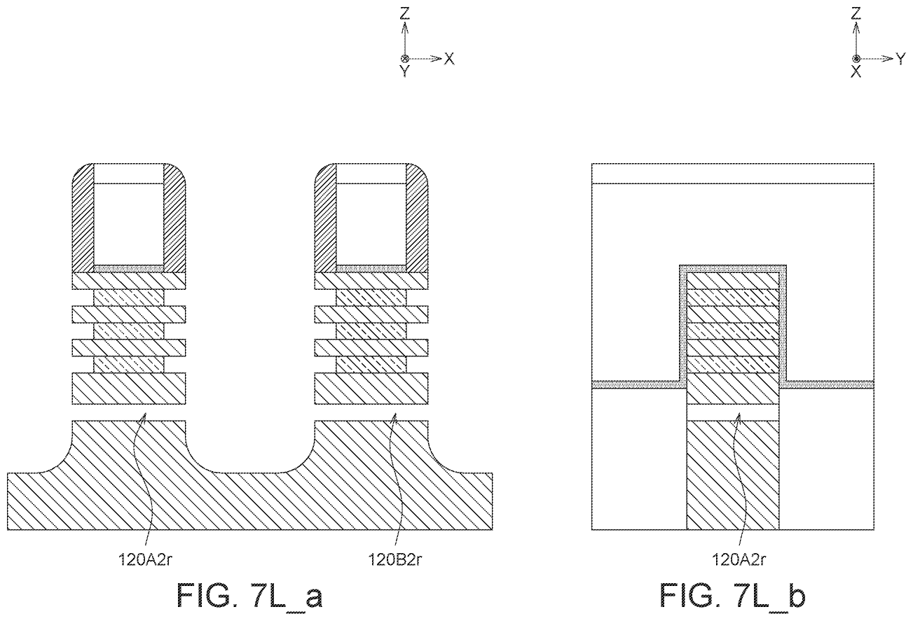

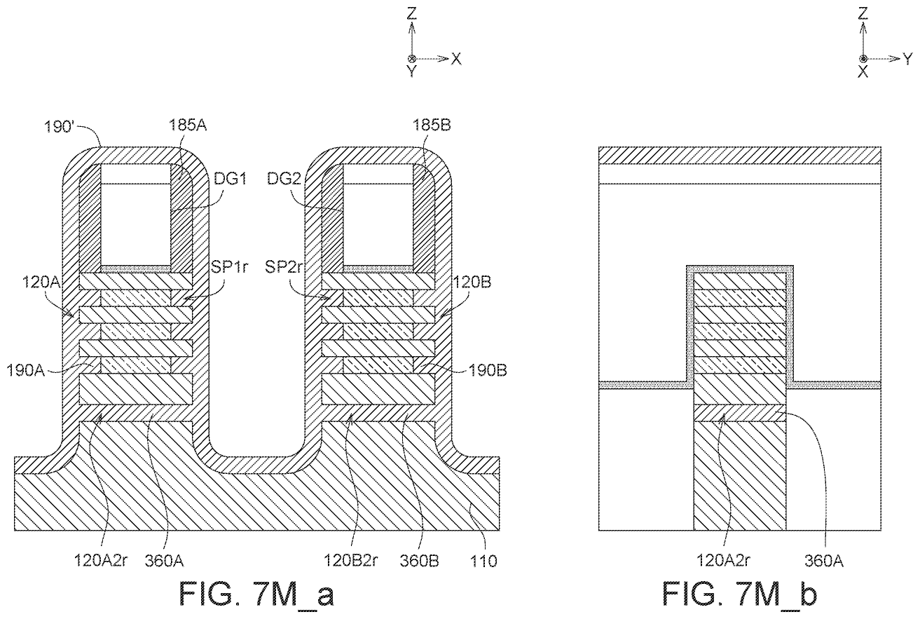

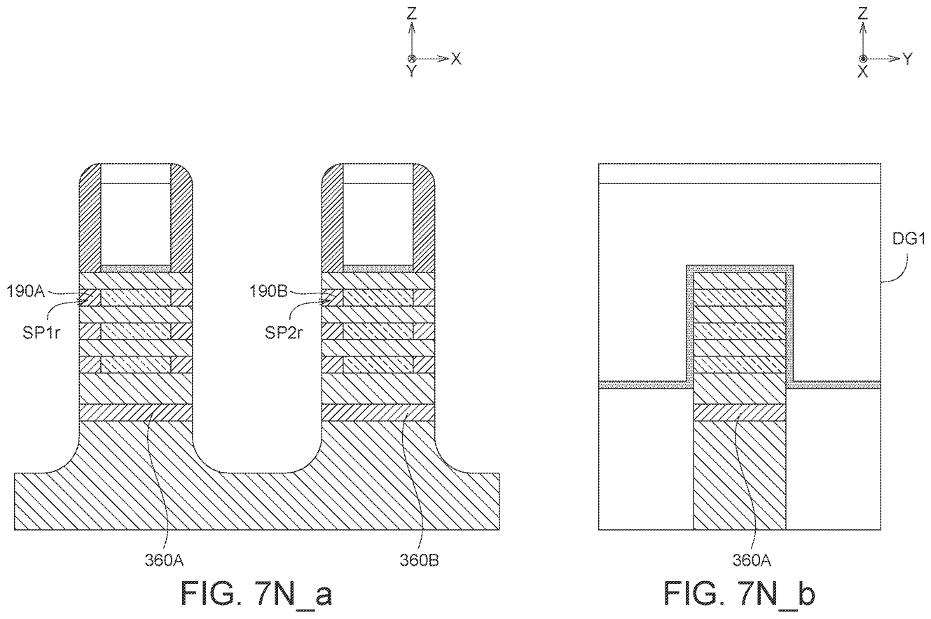

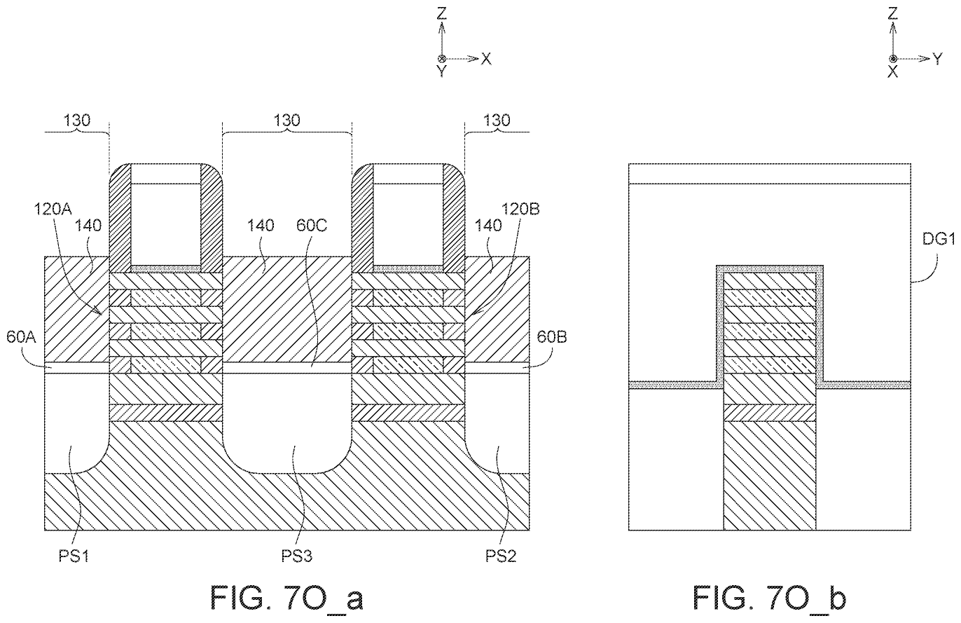

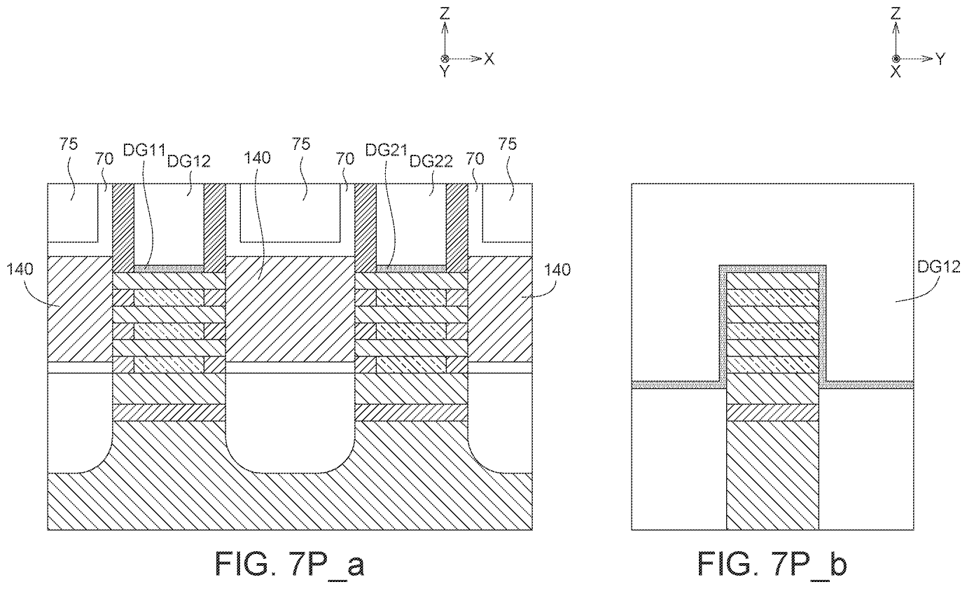

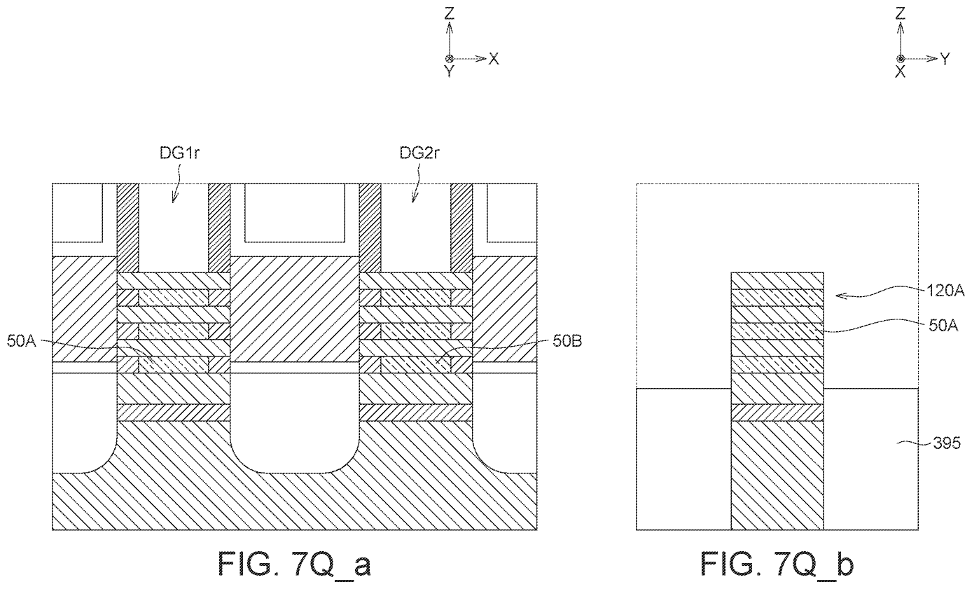

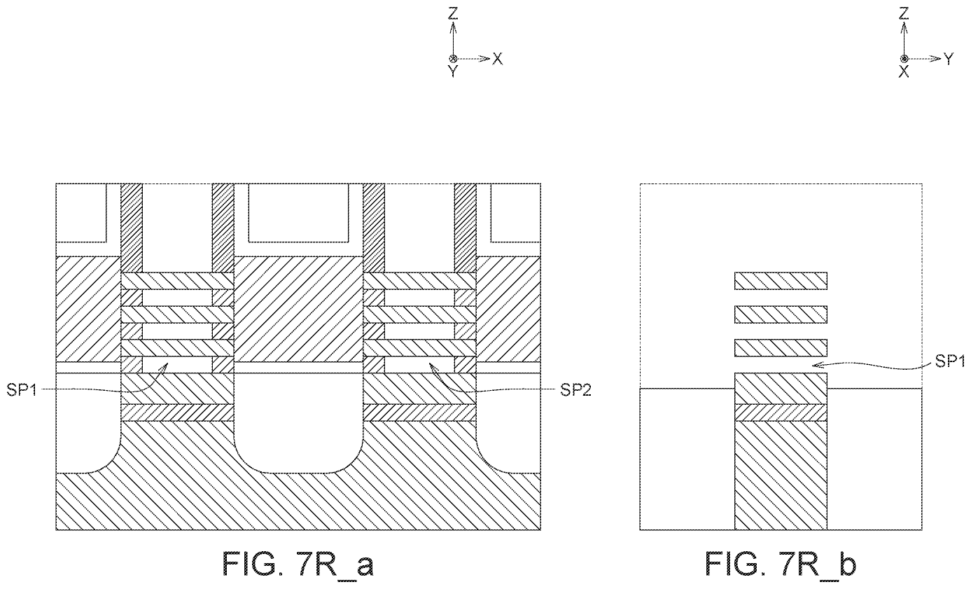

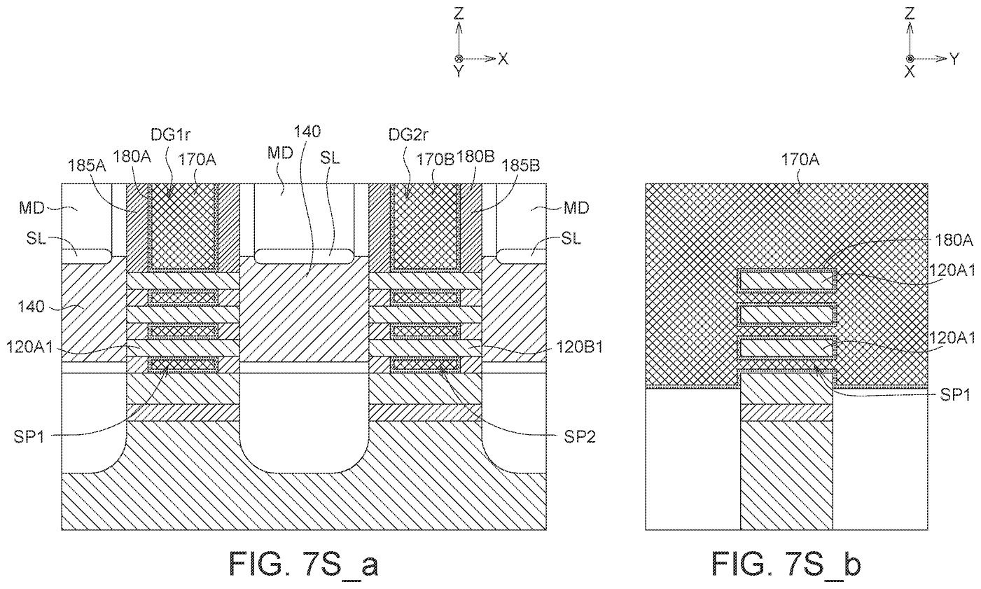

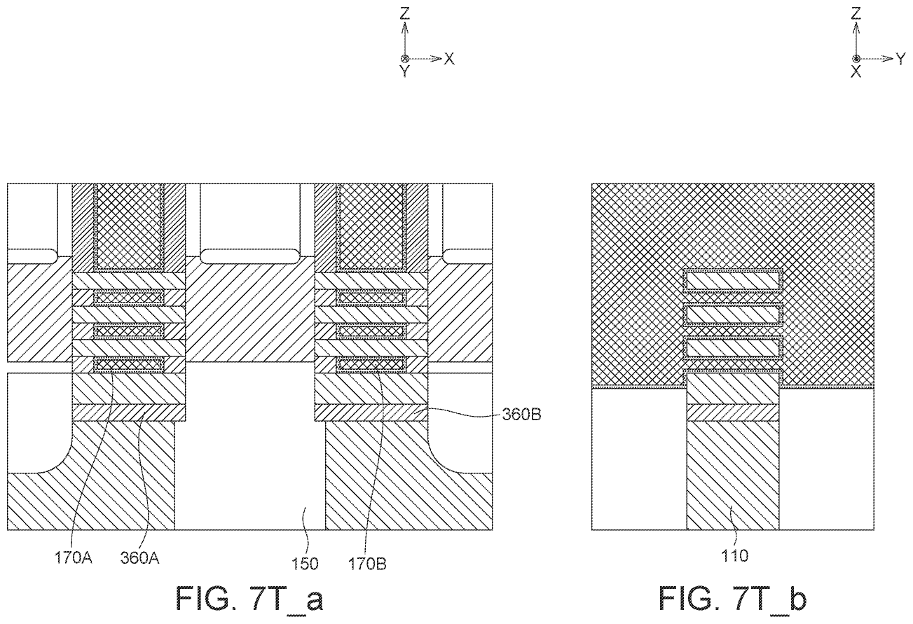

FIGS. 7A_a to 7T_b illustrate schematic diagrams of manufacturing processes of the semiconductor device 300 of FIGS. 3a and 3b.

The manufacturing processes of the semiconductor device 300 includes the processes the same as or similar to processes of the semiconductor device 100 shown in FIGS. 5A_a to 5C_b.

Then, as illustrated in FIGS. 7A_a and 7B_b, a portion of the oxide layer material 195′ of FIG. 5C_b is removed to form the oxide layer 395 by, for example, etching, etc. The oxide layer 395 is higher than the lowermost spacer layer 120A2L′. For example, the oxide layer 395 is higher than the upper surface 120A2u of the lowermost spacer layer 120A2L′ for covering the lateral surface of the lowermost spacer layer 120A2L′.

As illustrated in FIGS. 7B_a and 7B_b, the patterned first dummy gate structure DG1 is formed on the fin structure 120′. The first dummy gate structure DG1 includes the oxide layer DG11, the dummy gate layer DG12 and the mask layer DG13. The oxide layer DG11 is formed on the fin structures 120′ and the oxide layer 395. The dummy gate layer DG12 is formed over the oxide layer DG11, and the mask layer DG13 is formed over the dummy gate layer DG12. In an embodiment, the dummy gate layer DG12 may be deposited over the oxide layer DG11 and then planarized, such as by CMP, and then the mask layer DG13 may be deposited over the dummy gate layer DG12.

Similarly, the patterned second dummy gate structure DG2 is formed on the fin structure 120′. The second dummy gate structure DG2 includes the oxide layer DG21, the dummy gate layer DG22 and the mask layer DG23. The oxide layer DG21 is formed on the fin structures 120′ and the oxide layer 395. The dummy gate layer DG22 is formed over the oxide layer DG21, and the mask layer DG23 is formed over the dummy gate layer DG22. In an embodiment, the dummy gate layer DG22 may be deposited over the oxide layer DG21 and then planarized, such as by CMP, and then the mask layer DG23 may be deposited over the dummy gate layer DG22.

As illustrated in FIGS. 7C_a and 7C_b, the first spacer layer 185A over a lateral surface of the first dummy gate structure DG1 and the second spacer layer 185B over a lateral surface of the second dummy gate structure DG2 are formed by, for example, deposition, etc. Then, a portion of the fin structure 120′ is removed to form at least one active structure (at least include the first active structure 120A and the second active structure 120B) by, for example, anisotropic etching such as global SSD (GSSD) etching, etc. There are a plurality of the trenches formed a plurality of the active structures. For example, there is one trench 130 formed between the first active structure 120A and the second active structure 120B. The first active structure 120A includes a plurality of the sheets 120A1 and a plurality of the spacers 120A2, wherein one spacer 120A2 is formed between the adjacent two sheets 120A1. The second active structure 120B includes a plurality of the sheets 120B1 and a plurality of the spacers 120B2, wherein one spacer 120B2 is formed between the adjacent two sheets 120B1.

As illustrated in FIGS. 7D_a and 7D_b, a hard mask layer 30′ over the first dummy gate structure DG1, the second dummy gate structure DG2, the first spacer layer 185A, the second spacer layer 185B, the first active structure 120A and the second active structure 120B is formed by, for example, deposition, etc. The hard mask layer 30′ may be formed of a material including, for example, AlOx, etc.

As illustrated in FIGS. 7E_a and 7E_b, a block material over the hard mask layer 30′ is formed by, for example, coating, deposition, spinning, etc., and then a portion of the block material is removed to form at least one block 40 within the bottom of the trench 130 by etching back, etc. The block 40 has the upper surface 40u higher than the lowermost spacer 120A2L and the lowermost spacer layers 120B2L. For example, the upper surface 40u of the block 40 is higher than the upper surface 120A2u of the lowermost spacer 120A2L and the upper surface 120B2u of the lowermost spacer 120B2L.

As illustrated in FIGS. 7F_a and 7F_b, a portion of the hard mask layer 30′ is removed to form at least one hard mask 30 by, for example, etching back, etc. The hard mask 30 is retained during etching due to the blocking of the block 40. The hard mask 30 covers the lateral surface 120A2s of the lowermost spacer 120A2L and the lateral surface of the lowermost spacer 120B2L. As a result, the lowermost spacer 120A2L and the lowermost spacer 120B2L are not removed in the subsequent process, for example, process shown in FIGS. 7H_a and 7H_b.

As illustrated in FIGS. 7G_a and 7G b, the blocks 40 are removed to expose the hard mask 30 by, for example, etching, etc.

As illustrated in FIGS. 7H_a and 7H_b, the spacers 120A2 and the spacers 120B2 of FIG. 7G a which are not covered by the hard mask 30 are removed to form the first spaces SP1 and the second spaces SP2 by, for example, dry etching, etc. The lowermost spacers 120A2L and 120B2L are retained due to the blocking of the hard mask 30.

As illustrated in FIGS. 7I_a and 7I_b, the hard mask 30 is removed to expose the lowermost spacers 120A2L and 120B2L by, for example, etching, etc.

As illustrated in FIGS. 7J_a and 7J_b, the oxide material 50′ over the first active structure 120A, the second active structure 120B, the first dummy gate structure DG1, the second dummy gate structure DG2, the first spacer layer 185A, the second spacer layer 185B, the lowermost spacer 120A2L and the lowermost spacer 120B2L is formed by, for example, ALD, FCVD or a combination thereof. The oxide material 50′ fills the first spaces SP1 of the first active structure 120A and the second spaces SP2 of the second active structure 120B.

As illustrated in FIGS. 7K_a and 7K_b, a portion of the oxide material 50′ of FIG. 7J_a is removed to form a plurality of first oxide spacers 50A within the first spaces SP1 of the first active structure 120A and a plurality of second oxide spacers 50B within the second spaces SP2 of the second active structure 120B. The first oxide spacer 50A is recessed with respect to a lateral surface of the sheet to form a first recess SP1r, and the second oxide spacer 50B is recessed with respect to a lateral surface of the sheet to form a second recess SP2r.

As illustrated in FIGS. 7L_a and 7L_b, the lowermost spacer 120A2L and the lowermost spacer 120B2L of FIG. 7K_a are removed to form the lowermost first space 120A2r and the lowermost second space 120B2r by, for example, dry etching, etc.

As illustrated in FIGS. 7M_a and 7M_b, an inner spacer material 190′ over the substrate 110, the first active structure 120A, the second active structure 120B, the first spacer layer 185A, the second spacer layer 185B, the first dummy gate structure DG1, the second dummy gate structure DG2 is formed by, for example, depiction, etc. The inner spacer material 190′ includes a plurality of the first inner spacers 190A, a plurality of the second inner spacers 190B, the first insulation layer 360A and the second insulation layer 360B, wherein each first inner spacer 190A fills the first recess SP1r, each second inner spacer 190B fills the second recess SP2r, the first insulation layer 360A fills the lowermost first space 120A2r, and the second insulation layer 360B fills the lowermost second space 120B2r.

As illustrated in FIGS. 7N_a and 7N_b, a portion of the inner spacer material 190′ is removed by, for example, etching back, etc., but the first inner spacers 190A, the second inner spacers 190B, the first insulation layer 360A and the second insulation layer 360B are retained.

As illustrated in FIGS. 7O_a and 7O_b, a pure silicon layer, a block layer and at least one epitaxy 140 are formed. The pure silicon layer is formed within the bottom of each trench 130, the block layer is formed over the pure silicon layer, and the epitaxy 140 is formed over the block layer. Furthermore, the pure silicon layer includes the first pure silicon layer PS1, the second pure silicon layer PS2 and a third pure silicon layer PS3, wherein the third pure silicon layer PS3 is formed within the trench 130 between the first active structure 120A and the second active structure 120B, the first pure silicon layer PS1 and the third pure silicon layer PS3 are located at two opposite sides of the first active structure 120A, and the second pure silicon layer PS2 the third pure silicon layer PS3 are located at two opposite sides of the second active structure 120B. The block layer includes a first block layer 60A, a second block layer 60B and a third block layer 60C, wherein the first block layer 60A is formed over the first pure silicon layer PS1, the second block layer 60B is formed over the second pure silicon layer PS2, and the third block layer 60C is formed over the third pure silicon layer PS3.

As illustrated in FIGS. 7P_a and 7P_b, a portion of the structure of FIGS. 7O_a and 7O_b is removed by, for example, CMP. Furthermore, the mask layer DG13 and DG23 are removed.

As illustrated in FIGS. 7P_a and 7P_b, the bottom CESL (BCESL) layer 70 is formed over the epitaxies 140 by using, for example, deposition, such as CVD, PECVD, ALD, or the like. The bottom CESL 70 may be formed of a material including, for example, a dielectric material, such as silicon nitride, silicon oxide, silicon oxynitride, or the like. Then, the ILD layer 75 covering the bottom CESL layer 70 is formed by using, for example, deposition, such as CVD, PECVD, or FCVD, or the like. In addition, the ILD layer 75 may be planarized by, for example, CMP, etc. The ILD layer 75 may be formed of a dielectric including, for example, PSG, BSG, BPSG, USG, or the like. Other insulation materials formed by any acceptable process may be used.

As illustrated in FIGS. 7Q_a and 7Q_b, the oxide layer DG11 and dummy gate layer DG12 of the first dummy gate structure DG1 and the oxide layer DG21 and dummy gate layer DG22 of the second dummy gate structure DG2 in FIG. 7P_a are removed to form the first recess DG1r and the second recess DG2r respectively by, for example, dry etching, etc. After removal of the oxide layer DG11, the active structures (for example, the first active structure 120A and the second active structure 120B) are exposed.

As illustrated in FIGS. 7R_a and 7R_b, the first oxide spacers 50A and the second oxide spacers 50B in FIGS. 7Q_a and 7Q_b are removed to form a plurality of the first spaces SP1 and a plurality of the second spaces SP2 by, for example, dry etching, etc.

As illustrated in FIGS. 7S_a and 7S_b, the first high-k dielectric layer 180A covering the sheets 120A1 and the first spacer layer 185A is formed by, for example, ALD, etc. and the second high-k dielectric layer 180B covering the sheets 120B1 and the second spacer layer 185B is formed by, for example, ALD, etc. Then, the first metal gate 170A within the first recess DG1r and the first spaces SP1 and the second metal gate 170B within the second recess DG2r and the second spaces SP2 are formed. Then, at least one silicide layer SL is formed on the epitaxy 140, and at least one metal over diffusion MD is formed over the silicide layer SL.

As illustrated in FIGS. 7T_a and 7T_b, the back-side conductive via 150 passing through the substrate 110 is formed to connect the epitaxy 140 by in the SPR SAC process. The first insulation layer 160A could block the back-side conductive via 150 from being in contact with the first metal gate 170A, and the second insulation layer 160B could block the back-side conductive via 150 from being in contact with the second metal gate 170B.

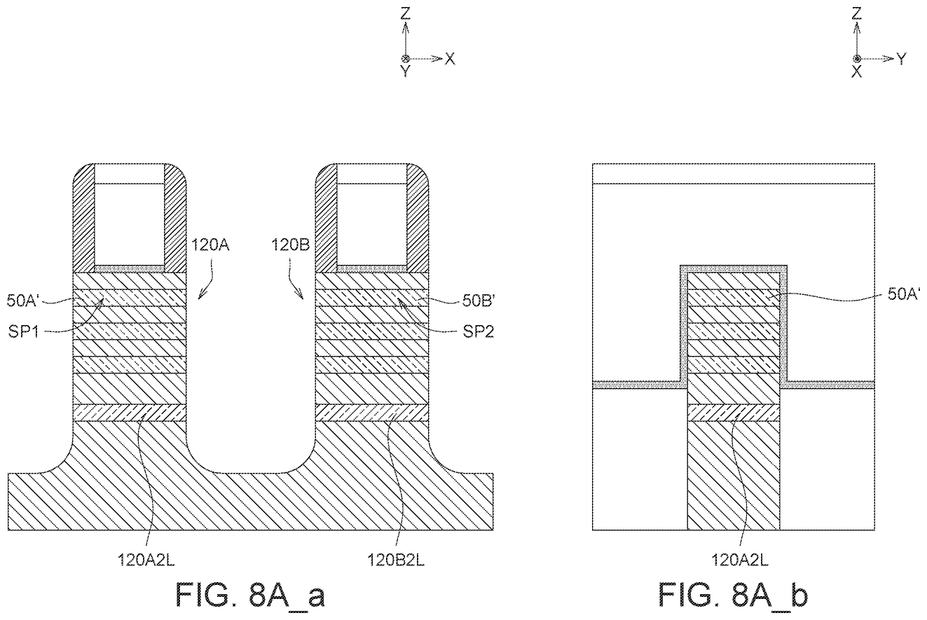

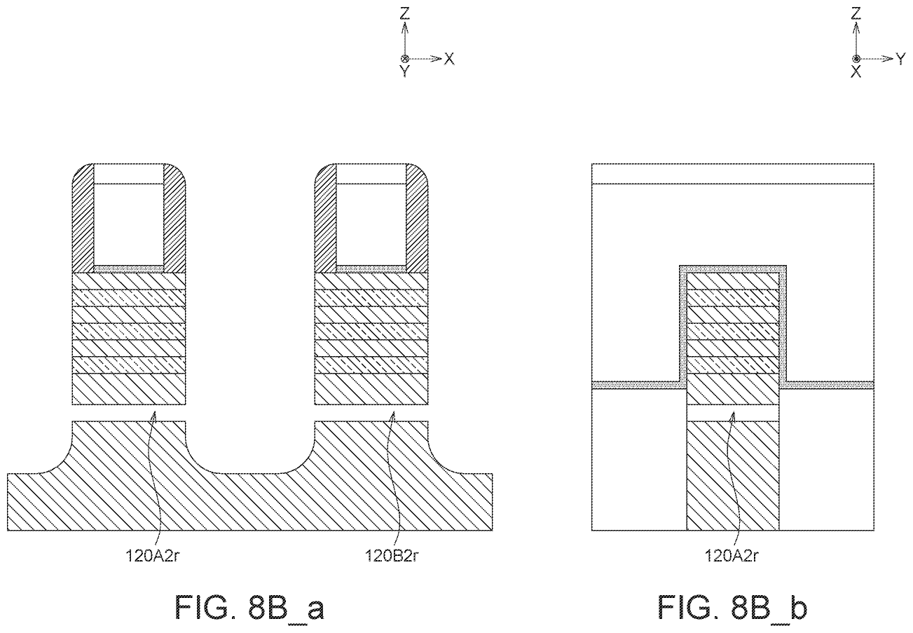

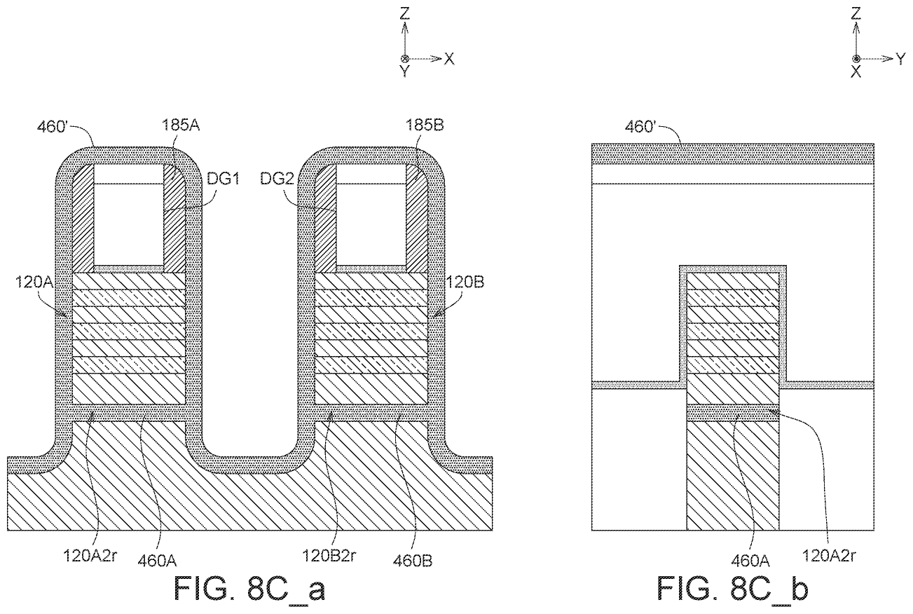

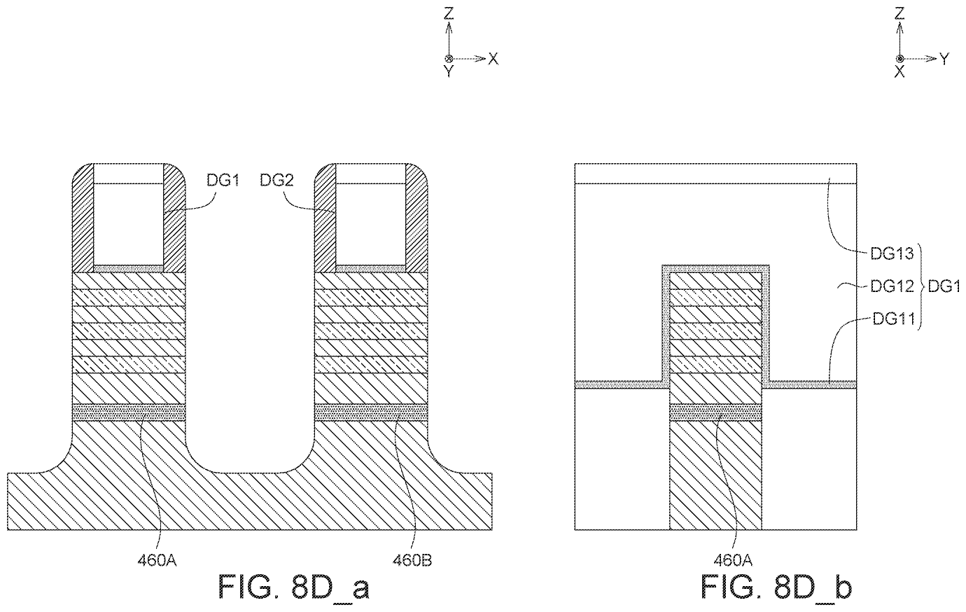

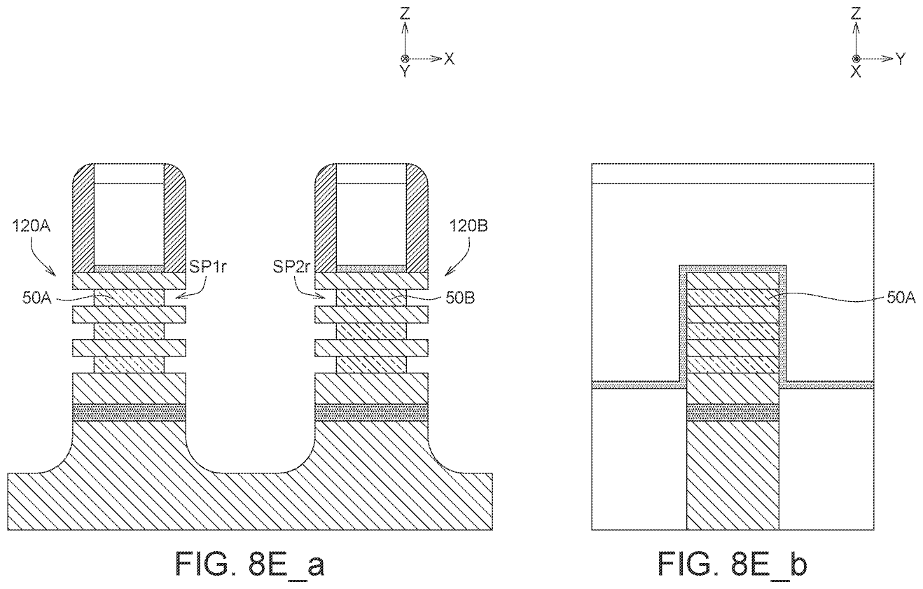

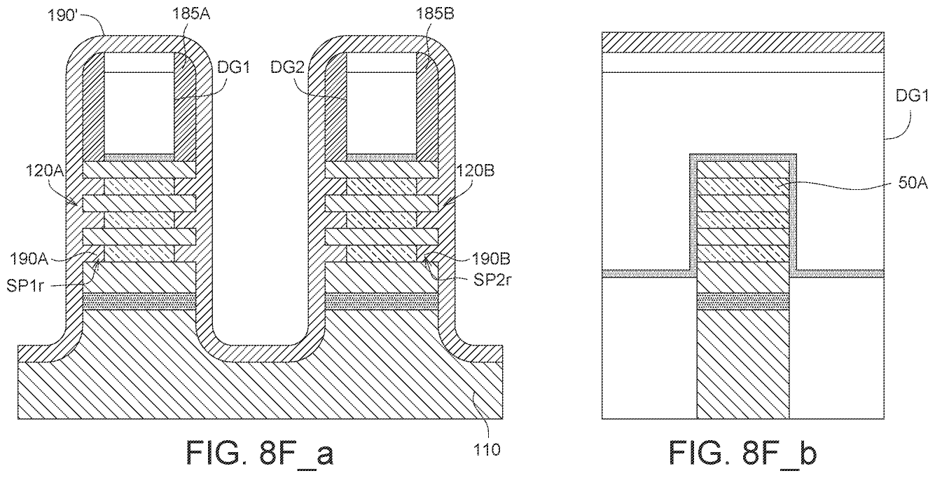

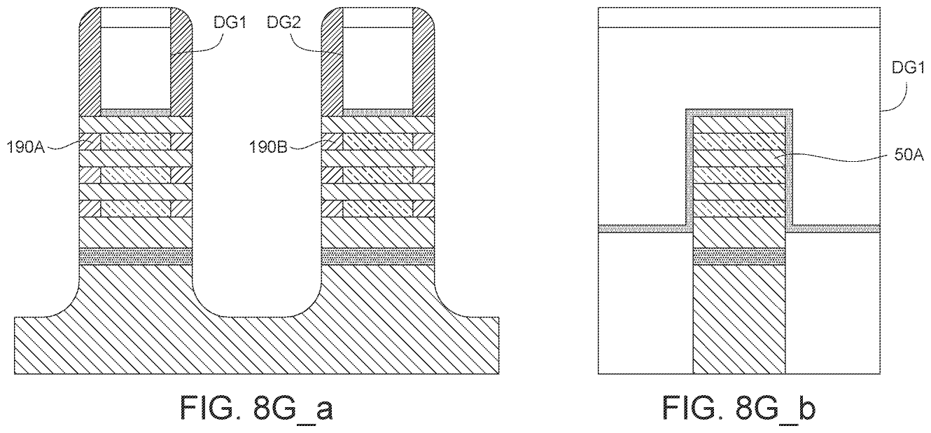

FIGS. 8A_a to 8G_b illustrate schematic diagrams of manufacturing processes of the semiconductor device 400 of FIGS. 4a and 4b.

The manufacturing processes of the semiconductor device 400 includes the processes the same as or similar to processes of the semiconductor device 300 shown in FIGS. 7A_a to 7J_b.

Then, as illustrated in FIGS. 8A_a and 8A_b, a portion of the oxide material 50′ of FIG. 7K_a is removed to form a plurality of first oxide spacers 50A′ within the first spaces SP1 of the first active structure 120A and a plurality of second oxide spacers 50B′ within the second spaces SP2 of the second active structure 120B. In the present embodiment, each first oxide spacer 50A′ fills up the whole of the corresponding first space SP1, and each second oxide spacer 50B′ fills up the whole of the corresponding second space SP2.

As illustrated in FIGS. 8B_a and 8B_b, the lowermost spacer 120A2L and the lowermost spacer 120B2L of FIG. 8A_a are removed to form the lowermost first space 120A2r and the lowermost second space 120B2r by, for example, dry etching, etc.

As illustrated in FIGS. 8C_a and 8C_b, a high-K layer material 460′ over the substrate 110, the first spacer layer 185A, the second spacer layer 185B, the first dummy gate structure DG1, the second dummy gate structure DG2, the first active structure 120A and the second active structure 120B is formed by, for example, deposition, etc. The high-K layer material 460′ includes the first insulation layer 460A and the second insulation layer 460B, wherein the first insulation layer 460A fills the lowermost first space 120A2r and the second insulation layer 460B fills the lowermost second space 120B2r.

As illustrated in FIGS. 8D_a and 8D_b, a portion of the high-K layer material 460′ is removed, but the first insulation layer 460A and the second insulation layer 460 are retained.

As illustrated in FIGS. 8E_a and 8E_b, a portion of the first oxide spacer 50A′ of FIG. 8D_a is removed to form the first oxide spacer 50A within the first space SP1 of the first active structure 120A, and a portion of the second oxide spacer 50B′ of FIG. 8D_a is removed to form the second oxide spacer 50B within the second space SP2 of the second active structure 120B. The first oxide spacer 50A is recessed with respect to the lateral surface of the sheet to form the first recess SP1r, and the second oxide spacer 50B is recessed with respect to the lateral surface of the sheet to form the second recess SP2r.

As illustrated in FIGS. 8F_a and 8F_b, the inner spacer material 190′ over the substrate 110, the first active structure 120A, the second active structure 120B, the first spacer layer 185A, the second spacer layer 185B, the first dummy gate structure DG1, the second dummy gate structure DG2 is formed by, for example, depiction, etc. The inner spacer material 190′ includes a plurality of the first inner spacers 190A and a plurality of the second inner spacers 190B, wherein each first inner spacer 190A fills the first recess SP1r, and each second inner spacer 190B fills the second recess SP2r.

As illustrated in FIGS. 8G_a and 8G_b, a portion of the inner spacer material 190′ is removed by, for example, etching back, etc., but the first inner spacers 190A and the second inner spacers 190B are retained.

Then, the follow-up processes for the semiconductor device 400 are the same as or similar to that of the semiconductor device 300, for example, the processes shown in FIGS. 7O_a to 7T_b.

The above description of illustrated implementations of the disclosure, including what is described in the Abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

These modifications may be made to the disclosure in light of the above detailed description. The terms used in the following claims should not be construed to limit the disclosure to the specific implementations disclosed in the specification and the claims. Rather, the scope of the disclosure is to be determined entirely by the following claims, which are to be construed in accordance with established doctrines of claim interpretation.

According to the present disclosure, a semiconductor device includes an insulation layer formed under the metal gate and extends to a lateral surface of the back-side conductive via, or extends between a lateral surface of a pure silicon layer and the lateral surface of the back-side conductive via.

Example embodiment 1: a semiconductor device includes a substrate, a first active structure, a first metal gate, a trench, an epitaxy and a back-side conductive via. The first active structure and a second active structure are formed on the substrate and arranged in a first direction. The first metal gate is formed on the first active structures. The trench passes through adjacent two of the first active structure and the second active structure in a second direction. The epitaxy formed on within the trench. The back-side conductive via is formed within the substrate and connecting the epitaxy. The first insulation layer is formed under the first metal gate and extending to a first lateral surface of the back-side conductive via.

Example embodiment 2 based on Example embodiment 1: the semiconductor device further includes a second metal gate and a second insulation layer. The second metal gate is formed on the second active structure. The second insulation layer is formed under the second metal gate and extends to a second lateral surface of the back-side conductive via.

Example embodiment 3 based on Example embodiment 1: the semiconductor device further includes a pure silicon layer. The pure silicon layer is formed on a bottom of another trench. The first insulation layer extends between the pure silicon layer and the back-side conductive via in the first direction.

Example embodiment 4 based on Example embodiment 1: the substrate has an upper surface on which the first active structure and the second active structure are formed, and the first insulation layer is formed on the upper surface of the substrate.

Example embodiment 5 based on Example embodiment 1: the first active structure includes a plurality of sheets, and the semiconductor device further includes a high-k dielectric layer covering the sheets. The high-k dielectric layer and the first insulation layer are formed of the same material.

Example embodiment 6 based on Example embodiment 1: the first active structure includes a plurality of sheets and a space, the space is formed between adjacent two of the sheets, and a portion of the metal gate is formed within the space. The semiconductor device further includes an inner spacer. The inner spacer is formed within the space. The inner spacer and the first insulation layer are formed of the same material.

Example embodiment 7 based on Example embodiment 1: the first insulation layer has a lateral surface, the first metal gate has a lateral surface, the lateral surface of the first insulation layer is closer to the first lateral surface of the back-side conductive via than the lateral surface of the first metal gate.

Example embodiment 8 based on Example embodiment 1: a semiconductor device further includes an oxide layer and a cushion layer. The oxide layer is formed over the substrate. The cushion layer is formed over oxide layer. The cushion layer is lower than the first metal gate and higher than the first insulation layer.

Example embodiment 9 based on Example embodiment 1: the first active structure includes a plurality of sheets and a space, the space is formed between adjacent two of the sheets, and the space has a first width, and the first insulation layer has a second width substantially equal to the first width.

Example embodiment 10: a manufacturing method for a semiconductor device includes the following steps: forming a fin structure on the substrate, wherein the fin structure extends in a first direction; forming a trench passing through the fin structure to form a first active structure and a second active structure, wherein the trench extends in a second direction; forming a first insulation layer within the first active structure; forming an epitaxy within the trench; forming a first metal gate within the first active structure, wherein the first insulation layer is formed under the first metal gate; and forming the back-side conductive via to connect the epitaxy, wherein the first insulation layer extends to a first lateral surface of the back-side conductive via.

Example embodiment 11 based on Example embodiment 10: the manufacturing method further includes: forming a second metal gate on the second active structure; and forming a second insulation layer within the second active structure. In forming the back-side conductive via to connect the epitaxy, the second insulation layer extends to a second lateral surface of the back-side conductive via.

Example embodiment 12 based on Example embodiment 10: the manufacturing method further includes: forming a pure silicon layer formed on a bottom of another trench. In forming the back-side conductive via to connect the epitaxy, the first insulation layer extends between the pure silicon layer and the back-side conductive via in the first direction.

Example embodiment 13 based on Example embodiment 10: the substrate has an upper surface on which the first active structure and the second active structure are formed, and in forming the first insulation layer within the first active structure, the first insulation layer is formed on the upper surface.

Example embodiment 14 based on Example embodiment 10: forming the trench passing through the fin structure to form the first active structure and the second active structure, the first active structure includes a plurality of sheets. The manufacturing method further includes: forming a high-k dielectric layer covering the sheets, wherein the high-k dielectric layer and the first insulation layer are formed of the same material.

Example embodiment 15 based on Example embodiment 10: forming the trench passing through the fin structure to form the first active structure and the second active structure, the first active structure includes a plurality of sheets and a space, the space is formed between adjacent two of the sheets; in forming the first metal gate within the first active structure, a portion of the metal gate is formed within the space; the manufacturing method further includes: forming an inner spacer within the space, wherein the inner spacer and the first insulation layer are formed of the same material.

Example embodiment 16 based on Example embodiment 10: in forming the first insulation layer within the first active structure, the first insulation layer has a lateral surface; in forming the first metal gate within the first active structure, the first metal gate has a lateral surface, and the lateral surface of the first insulation layer is closer to the first lateral surface of the back-side conductive via than the lateral surface of the first metal gate.

Example embodiment 17 based on Example embodiment 10: the manufacturing method further includes: forming an oxide layer over the substrate; and forming a cushion layer over oxide layer, wherein the cushion layer is lower than the first metal gate and higher than the first insulation layer.

Example embodiment 18: a manufacturing method for a semiconductor device includes the following steps: forming a fin structure on the substrate, wherein the fin structure extends in a first direction, forming a trench passing through the fin structure to form an active structure, wherein the trench extends in a second direction, the active structure includes a plurality of sheets and a spacer, the spacer is formed between adjacent two of the sheets, and each spacer is formed of silicon-germanium; forming a hard mask within a bottom of the trench to cover a lateral surface of the lowermost spacer; removing the spacer which is not covered by the hard mask to form a plurality of spaces, wherein the lowermost spacer is retained; removing the hard mask to expose the lowermost spacer; forming an oxide spacer within the space; removing the lowermost spacer to form a lowermost space; and forming the insulation layer within the lowermost space.

Example embodiment 19 based on Example embodiment 18: forming the insulation layer within the lowermost space further includes: forming an inner spacer and within the space, wherein the inner spacer and the insulation layer are formed of the same material.

Example embodiment 20 based on Example embodiment 18: in forming the insulation layer within the lowermost space, the insulation layer is formed of a high-k dielectric material; after forming the insulation layer within the lowermost space, the manufacturing method further includes: forming an inner spacer and within the space.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A semiconductor device, comprising:
a substrate;
a first active structure and a second active structure formed on the substrate and arranged in a first direction;
a first metal gate formed on the first active structure;
a trench passing through adjacent two of the first active structure and the second active structure in a second direction;
an epitaxy formed on within the trench;
a back-side conductive via formed within the substrate and connecting the epitaxy;
a first insulation layer formed under the first metal gate and extending to a first lateral surface of the back-side conductive via.

2. The semiconductor device as claimed in claim 1, further comprising:
a second metal gate formed on the second active structure; and
a second insulation layer formed under the second metal gate and extending to a second lateral surface of the back-side conductive via.

3. The semiconductor device as claimed in claim 1, further comprising:
a pure silicon layer formed on a bottom of another trench;
wherein the first insulation layer extending between the pure silicon layer and the back-side conductive via in the first direction.

4. The semiconductor device as claimed in claim 1, wherein the substrate has an upper surface on which the first active structure and the second active structure are formed, and the first insulation layer is formed on the upper surface of the substrate.

5. The semiconductor device as claimed in claim 1, wherein the first active structure comprises a plurality of sheets, and the semiconductor device further comprises:
a high-k dielectric layer covering the sheets;
wherein the high-k dielectric layer and the first insulation layer are formed of the same material.

6. The semiconductor device as claimed in claim 1, wherein the first active structure comprises a plurality of sheets and a space, the space is formed between adjacent two of the sheets, a portion of the metal gate is formed within the space; the semiconductor device further comprises:
an inner spacer formed within the space;
wherein the inner spacer and the first insulation layer are formed of the same material.

7. The semiconductor device as claimed in claim 1, wherein the first insulation layer has a lateral surface, the first metal gate has a lateral surface, the lateral surface of the first insulation layer is closer to the first lateral surface of the back-side conductive via than the lateral surface of the first metal gate.

8. The semiconductor device as claimed in claim 1, further comprising:
an oxide layer formed over the substrate; and
a cushion layer formed over oxide layer;
wherein the cushion layer is lower than the first metal gate and higher than the first insulation layer.

9. The semiconductor device as claimed in claim 1, wherein the first active structure comprises a plurality of sheets and a space, the space is formed between adjacent two of the sheets, and the space has a first width, and the first insulation layer has a second width substantially equal to the first width.

10. A manufacturing method for a semiconductor device, comprising:
forming a fin structure on the substrate, wherein the fin structure extends in a first direction;
forming a trench passing through the fin structure to form a first active structure and a second active structure, wherein the trench extends in a second direction;
forming a first insulation layer within the first active structure;
forming an epitaxy within the trench;
forming a first metal gate within the first active structure, wherein the first insulation layer is formed under the first metal gate; and
forming the back-side conductive via to connect the epitaxy, wherein the first insulation layer extends to a first lateral surface of the back-side conductive via.

11. The manufacturing method as claimed in claim 10, further comprising:
forming a second metal gate on the second active structure; and
forming a second insulation layer within the second active structure;
wherein in forming the back-side conductive via to connect the epitaxy, the second insulation layer extends to a second lateral surface of the back-side conductive via.

12. The manufacturing method as claimed in claim 10, further comprising:
forming a pure silicon layer formed on a bottom of another trench;
wherein in forming the back-side conductive via to connect the epitaxy, the first insulation layer extends between the pure silicon layer and the back-side conductive via in the first direction.

13. The manufacturing method as claimed in claim 10, wherein the substrate has an upper surface on which the first active structure and the second active structure are formed, and in forming the first insulation layer within the first active structure, the first insulation layer is formed on the upper surface.

14. The manufacturing method as claimed in claim 10, wherein forming the trench passing through the fin structure to form the first active structure and the second active structure, the first active structure comprises a plurality of sheets; the manufacturing method further comprise:
forming a high-k dielectric layer covering the sheets, wherein the high-k dielectric layer and the first insulation layer are formed of the same material.

15. The manufacturing method as claimed in claim 10, wherein forming the trench passing through the fin structure to form the first active structure and the second active structure, the first active structure comprises a plurality of sheets and a space, the space is formed between adjacent two of the sheets; in forming the first metal gate within the first active structure, a portion of the metal gate is formed within the space; the manufacturing method further comprises:
forming an inner spacer within the space, wherein the inner spacer and the first insulation layer are formed of the same material.

16. The manufacturing method as claimed in claim 10, wherein in forming the first insulation layer within the first active structure, the first insulation layer has a lateral surface; in forming the first metal gate within the first active structure, the first metal gate has a lateral surface, and the lateral surface of the first insulation layer is closer to the first lateral surface of the back-side conductive via than the lateral surface of the first metal gate.

17. The manufacturing method as claimed in claim 10, further comprising
forming an oxide layer over the substrate; and
forming a cushion layer over oxide layer, wherein the cushion layer is lower than the first metal gate and higher than the first insulation layer.

18. A manufacturing method for a semiconductor device, comprising:
forming a fin structure on the substrate, wherein the fin structure extends in a first direction;
forming a trench passing through the fin structure to form an active structure, wherein the trench extends in a second direction, the active structure comprises a plurality of sheets and a spacer, the spacer is formed between adjacent two of the sheets, and each spacer is formed of silicon-germanium;
forming a hard mask within a bottom of the trench to cover a lateral surface of the lowermost spacer;
removing the spacer which is not covered by the hard mask to form a plurality of spaces, wherein the lowermost spacer is retained;
removing the hard mask to expose the lowermost spacer;
forming an oxide spacer within the space;
removing the lowermost spacer to form a lowermost space; and
forming the insulation layer within the lowermost space.

19. The manufacturing method as claimed in claim 18, wherein forming the insulation layer within the lowermost space further comprises:
forming an inner spacer and within the space, wherein the inner spacer and the insulation layer are formed of the same material.

20. The manufacturing method as claimed in claim 18, wherein in forming the insulation layer within the lowermost space, the insulation layer is formed of a high-k dielectric material; after forming the insulation layer within the lowermost space, the manufacturing method further comprises:
forming an inner spacer and within the space.
